(19) United States
(12) Patent Application Publication
(10) Pub. No.: US 2009/0188558 A1
(43) Pub. Date: Jul. 30, 2009

(54) PHOTOVOLTAIC DEVICES HAVING METAL OXIDE ELECTRON-TRANSPORT LAYERS

(75) Inventors: Kwan-Yue Jen, Kenmore, WA (US); Hin-Lap Yip, Seattle, WA (US); Steven K. Hau, Tucson, WA (US); Hong Ma, Bothell, WA (US)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(73) Assignee: UNIVERSITY OF WASHINGTON, Seattle, WA (US)

(21) Appl. No.: 12/360,058

(22) Filed: Jan. 26, 2009

Related U.S. Application Data
(60) Provisional application No. 61/117,007, filed on Nov. 21, 2008.
(60) Provisional application No. 61/023,749, filed on Jan. 25, 2008.

(51) Int. Cl. H01L 31/00; H01L 33/00

(52) U.S. Cl. 136/256; 438/57; 257/79; 257/E31.001; 257/E33.001

(57) ABSTRACT

Optoelectronic devices in both traditional and inverted configurations are provided that include an electron-transport layer. The electron-transport layer includes a metal oxide layer and a monolayer. Methods for making and using the devices are also provided.

### CROSS-REFERENCE TO RELATED APPLICATION

This application claims the benefit of U.S. Provisional Patent Application No. 61/023,749, filed on Jan. 25, 2008, and U.S. Provisional Patent Application No. 61/117,007, filed Nov. 21, 2008, each incorporated herein by reference in its entirety.

### STATEMENT OF GOVERNMENT LICENSE RIGHTS

This invention was made with Government support under Grant No. DMR-0120967, awarded by The National Science Foundation. The Government has certain rights in the invention.

### BACKGROUND

Organic (e.g., polymer) photovoltaic (PV) devices (also known as solarcells) are considered an important option for inexpensive renewable energy because they are amenable to fabrication by low-cost and large-area printing and coating technologies on lightweight, flexible substrates. Recent efforts to improve PV devices include a focus on fundamental device issues such as an improvement of device physics, optimization of material morphologies using processing methods, and the development of high performance materials. The combined effect of such optimizations has led to power-conversion efficiencies (PCE) of about 5%. However, an efficiency of at least 10% is likely required for practical applications.

A typical PV device, as known in the prior art, is illustrated in FIG. 1A. The PV device 100 includes a first electrode 105, a photovoltaic layer 110, and a second electrode 115. Typically, one of the electrodes 105 or 115 is a transparent conductor, such as indium-tin oxide (ITO), and the other electrode is a metal, such as aluminum. The photovoltaic layer 110 is composed of a material that utilizes the energy from incident electromagnetic radiation (e.g., visible light) to form free carriers, such as holes and electrons. The work functions of the electrodes 105 and 115 create an energetic state of the device 100 such that holes will flow to a hole-collecting electrode (e.g., 115), and electrons will flow to an electron-collecting electrode (e.g., 105). The holes and electrons generated in the photovoltaic layer 110 migrate towards their respective electrodes for collection, and electrical current is generated. When the electrodes 105 and 115 are connected to a device (e.g., a battery or electrical circuit) in need of electricity, current flows to the device.

The basic device 110 illustrated in FIG. 1A can be improved to increase performance through the incorporation of several optional layers.

Referring to FIG. 1B, a complex PV device 150 is illustrated having several optional layers. The electron-collecting electrode 105′ is illustrated at the top of the device 150.

The optional electron-transporting layer 106 forms an intermediary layer between the photovoltaic layer 110′ and the electron-collecting electrode 105′, such that electrons are allowed to pass favorably through the electron-transporting layer 106 and holes are blocked.

A hole-transporting layer 111 is also optional in the device 150 and forms an intermediary layer between the photovoltaic layer 110′ and the hole-collecting electrode 115′ such that holes are favorably passed through the hole-transporting layer 111 and electrons are blocked.

Finally, an optional substrate 120 is illustrated abutting the hole-collecting electrode 115′. It will be appreciated that in another embodiment, a substrate can alternatively abut the electron-collecting electrode 105′ instead of the hole-collecting electrode 115′. A typical prior art photovoltaic device 150 is fabricated on a substrate 120 of plastic- or glass-coated indium-tin oxide (ITO). Because ITO is typically sold pre-coated on glass or plastic substrates, the hole-collecting electrode (ITO) is essentially tied to the substrate when fabricating devices. Thus, the substrate 120 also acts as the hole-collecting electrode 115′ when an ITO-coated glass or plastic substrate is used for device fabrication.

Typical materials for the electron-collecting electrode 105 include aluminum, silver, and gold.

Typical electron-transport layer 106 materials include metal oxides, such as zinc oxide, indium, tin, cerium, and titanium oxide.

Materials useful in the photovoltaic layer 110 include any material or materials capable of generating free carriers when exposed to electromagnetic radiation. Such photovoltaic materials are well known to those of skill in the art and include both inorganic and organic materials. Typical p-type photovoltaic materials include conjugated polymers known to those of skill in the art. Typical n-type materials include organic materials and inorganic crystals (e.g., nanocrystals) such as titanium oxide (TiO₂), zinc oxide (ZnO), cadmium selenium (CdSe), lead sulfide (PbS), and lead selenium (PbSe). A particularly useful photovoltaic layer 110 includes a bulk heterojunction material that is a composite of both p-type and n-type semiconductors, such as a polymer (e.g., polyhexylthiophene) and a fullerene (such as [6,6]-phenyl-C₆₁-butyric acid methyl ester, commonly called PCBM).

Representative hole-transport materials are known to those of skill in the art. A preferred hole-transport layer 111 material is poly(3,4-ethylenedioxythiophene) poly(styrenesulfonate) (PEDOT:PSS).

Typical hole-collecting electrode 115 materials include indium-tin oxide and other transparent conductive materials.

For polymer PV devices, the nature of the electrical contacts between the photovoltaic layer 110 and electrodes 105 and 115 is one of the most critical factors in determining device characteristics, such as the short-circuit current density (J_{sc}), open-circuit voltage (V_{oc}), and the fill factor (FF). Because the series resistance (Rₛ) in a PV device is attributed to the bulk conductivity of each of the functional layers and the contact resistance between them, materials with high charge-carrier mobility and ohmic contact at the interfaces are required to obtain high J_{sc}. Good matching of the Fermi levels of the electrodes 105 and 115 to the lowest unoccupied molecular orbital (LUMO) of the electron acceptor and the highest occupied molecular orbital (HOMO) of the electron donor is also needed to maximize the V_{OC}. Another important parameter, the parallel resistance (Rₚ) (or shunt resistance), is determined by the quality of the thin films and their interfaces with other device layers. Small Rₚ originates from the loss of charge carriers through leakage paths, including pinholes in the films and the recombination and trapping of the carriers during their transit through the cell, leading to a decrease in the device performance.

Modification of electrodes 105 and 110 has been employed to improve contact with the photovoltaic layer. In traditional devices, when indium-tin oxide is used as the hole-collecting electrode 115, a thin buffer layer of a conductive polymer, such as PEDOT:PSS, is often used to increase the work function of ITO for effective hole collection.

At the electron-collecting electrode, a thin film of a low-work-function metal, such as Al (4.3 eV), prepared from thermal deposition has been used to collect electrons. By inserting a layer of LiF between Al and the active organic layer, device performance is improved through the formation of a favorable dipole moment across the junction, which facilitates better electron collection.

Despite improvements of organic-based PV devices, efficiency has not reached the level required for commercial applications. Thus, new device designs and materials for integration into such devices are required to further improve efficiency.

### SUMMARY OF THE INVENTION

In one aspect, a photovoltaic device including an enhancement layer is provided. In one embodiment, the device includes a hole-collecting electrode, a photovoltaic layer, an electron-collecting electrode, and an electron-transport layer that includes a metal oxide and a monolayer, located intermediate the electron-collecting electrode and the photovoltaic layer.

In another aspect, a method for fabricating a photovoltaic device including an enhancement layer is provided. In one embodiment, the method includes forming a photovoltaic layer on a hole-collecting electrode, forming a metal oxide layer on the photovoltaic layer, forming a monolayer on the metal oxide layer, and forming an electron-collecting electrode on the monolayer.

In another aspect, a method for making an inverted photovoltaic device is provided. In one embodiment, the method includes forming a metal oxide layer on an electron-collecting electrode, forming a monolayer on the metal oxide layer, forming a photovoltaic layer on the monolayer, and forming a hole-collecting electrode on the photovoltaic layer.

In another aspect, a method for producing electrical current from electromagnetic radiation is provided. In one embodiment, the method includes exposing the photovoltaic layer of a photovoltaic device of the invention to electromagnetic radiation of a wavelength sufficient to generate electrons and holes in the photovoltaic layer.

In another aspect, an optoelectronic device is provided that includes the enhancement layer. In one embodiment, the optoelectronic device includes an anode, an active layer, a cathode, and an electron-transport layer that includes a metal oxide and a monolayer intermediate the active layer and at least one of the anode and cathode.

### DESCRIPTION OF THE DRAWINGS

The foregoing aspects and many of the attendant advantages of this invention will become more readily appreciated as the same become better understood by reference to the following detailed description, when taken in conjunction with the accompanying drawings, wherein:

FIGS. 1A and 1B are diagrammatic cross-sectional views of prior art photovoltaic devices;

FIG. 2 is a diagrammatic cross-sectional view of a representative photovoltaic device in accordance with the embodiments described herein;

FIG. 3A is a diagrammatic cross-sectional view of a representative photovoltaic device in accordance with the embodiments described herein;

FIG. 3B is a detailed view of a portion of the photovoltaic device illustrated in FIG. 3A;

FIGS. 4A-4C are graphs plotting current versus voltage for representative devices in accordance with the embodiments described herein;

FIGS. 5A-5C are atomic force micrographs of layers of a representative photovoltaic devices formed in accordance with the embodiments described herein;

FIGS. 6A-6C are graphs plotting current versus voltage for representative devices in accordance with the embodiments described herein and control devices;

FIG. 7 is a flowchart illustrating a method for making a photovoltaic device in accordance with the embodiments described herein;

FIGS. 8A-8D are perspective illustrations of the stages of the method for making a photovoltaic device in accordance with the embodiments described herein;

FIG. 9 is a flowchart illustrating a method for making an inverted photovoltaic device in accordance with the embodiments described herein;

FIGS. 10A-10D illustrate the stages of the method for making a representative inverted photovoltaic device in accordance with the embodiments described herein;

FIG. 11 is a diagrammatic illustration of a representative system useful for generating electrical current using a photovoltaic device in accordance with the embodiments described herein;

FIG. 12 is a diagrammatic illustration of a representative optoelectronic device in accordance with the embodiments described herein;

FIG. 13 is a scheme illustrating the synthesis of a fullerene-containing molecule useful as a monolayer material in accordance with the embodiments described herein;

FIG. 14A is a graph plotting current versus voltage for a representative bulk heterojunction inverted photovoltaic device in accordance with the embodiments described herein; and

FIG. 14B is a graph plotting current versus voltage for a representative heterojunction inverted photovoltaic device in accordance with the embodiments described herein.

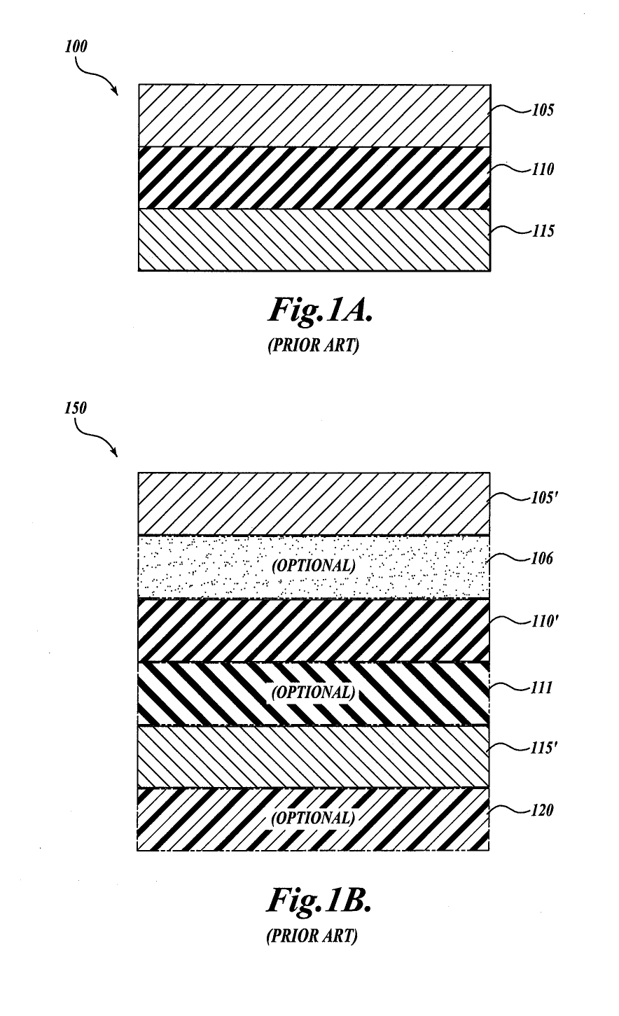

### DETAILED DESCRIPTION OF THE INVENTION

Photovoltaic (PV) devices are provided that include an electron-transporting layer that is a bilayer of a metal oxide and a monolayer coating at least one surface of the metal oxide layer. The combined metal oxide layer and monolayer are referred to herein interchangeably as the “electron-transport layer” and the “enhancement layer.” The enhancement layer is useful for enhancing the performance (e.g. efficiency) of PV devices. The enhancement layer is particularly useful for modifying the work function of the electron-collecting electrode in a PV device such that the contact between the electron-collecting electrode, through the enhancement layer, to the photovoltaic layer is ohmic, thus allowing for maximum device efficiency to be achieved. Additionally, the enhancement layer improves the extraction of electrons from the photovoltaic layer and enables the efficient movement of extracted electrons through the electron-transport layer to the electron-collecting electrode, so as to facilitate charge collection. As will be described further below, devices formed in accordance with the embodiments described herein demonstrate up to a 4.21% power-conversion efficiency (PCE), an improvement of nearly an order of magnitude when compared to devices formed without the enhancement layer.

In one aspect, a photovoltaic device including an enhancement layer is provided. In one embodiment, the device includes a hole-collecting electrode, a photovoltaic layer, an electron-collecting electrode, and an electron-transport layer that includes a metal oxide and a monolayer, located intermediate the electron-collecting electrode and the photovoltaic layer.

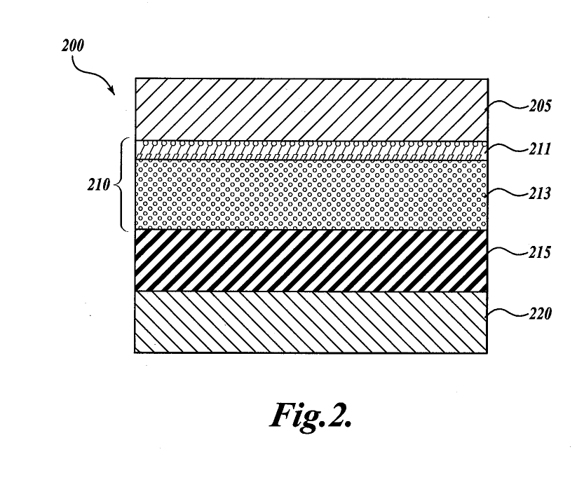

The photovoltaic device provided may be better understood with reference to FIG. 2, a diagrammatic illustration of a representative PV device in accordance with the embodiments described herein. Referring to FIG. 2, a PV device 200 is provided having an electron-collecting electrode 205, an enhancement layer 210 that includes a monolayer 211, and a metal oxide 213. Additionally, the device 200 includes a photovoltaic layer 215 and a hole-collecting electrode 220.

The electron-collecting electrode 205 (also referred to as a cathode) and the hole-collecting electrode 210 (also referred to as an anode) can be formed using materials known to those of skill in the art. Representative materials include metals, conductive polymers, and compound materials, such as indium-tin oxide. Representative metals include aluminum, copper, silver, gold, nickel, palladium, and platinum. A representative conductive polymer is PEDOT:PSS. The materials used as the electrodes 205 and 220 are selected according to device design principles known to those of skill in the art such that the work functions of the materials facilitate the extraction of generated free carriers from the photovoltaic layer 215 during device operation. In representative PV devices, indium-tin oxide is used as the hole-collecting electrode 220 and a metal, such as aluminum, is used as the electron-collecting electrode 205.

Representative photovoltaic materials useful in the device 200 include organic and inorganic photovoltaic materials. Representative organic photovoltaic materials include polymers, oligomers, and small molecules capable of individually, or in a composite, producing free carriers when irradiated with electromagnetic radiation (e.g., visible light). In a preferred embodiment, the photovoltaic layer 215 is a bulk heterojunction (BHJ) material that is a composite of an n-type and p-type semiconductor. In one embodiment, the BHJ includes a blend of one or more π-conjugated polymers and fullerenes. In a further preferred embodiment, the p-type material is a polymer, such as a poly(3-hexylthiophene) (P3HT), and the n-type material is a fullerene-containing compound, such as [6,6]-phenyl-C₆₁-butyric acid methyl ester, commonly referred to as PCBM. Other fullerene compounds include PC71PM ([6,6]-phenyl-C71-butyric acid methyl ester).

The enhancement layer 210 includes at least two components, a metal oxide layer 213 and a monolayer 211. As illustrated in the exemplary embodiment of FIG. 2, the monolayer 211 is intermediate the metal oxide 213 and the electron-collecting electrode 205. As will be discussed below, the monolayer 211 may also be intermediate the metal oxide 213 and the photovoltaic layer 215.

The metal oxide layer provides electron-transporting properties to the device. Representative metal oxide layer 213 materials include zinc oxide and titanium oxide, both of which enhance electron-transport between the photovoltaic layer 215 and the electron-collecting electrode 205. Metal oxides can be formed in many morphologies, including nanoparticles, annealed sol-gels, and thin continuous films. In a preferred embodiment, the metal oxide layer 213 is formed using nanoparticle zinc oxide. The electrical and electronic properties of metal oxides can be tuned by modifying their surfaces with a monolayer (e.g., SAM). As will be described in more detail below, monolayers provide a versatile mechanism to engineer the contact between the metal oxide and other layers of the device (e.g., electrodes).

A preferred representative metal oxide, zinc oxide (ZnO), is a large bandgap n-type semiconductor with a conduction band (CB) and valence band (VB) with respect to vacuum equal to 4.4 eV and 7.6 eV, respectively. The conduction band edge of ZnO is lower in energy than that of the LUMO of the representative photovoltaic layer BHJ material, PCBM (4.3 eV), which facilitates efficient electron transfer and extraction from the BHJ. In addition, the low-lying VB of ZnO can also effectively prevent hole carriers in the polymer from reaching the electron-collecting electrode. Other advantages of using ZnO as a component of the enhancement layer include its high electron mobility (0.066 cm²/Vs) and solution processability.

The monolayer 211 modifies at least one surface of the metal oxide layer 213. Representative monolayer materials include self-assembled monolayers. Self-assembled monolayers having electron-transporting properties are preferred, and such electron-transporting properties typically arise in functionalized π-conjugated compounds. Representative functionalized π-conjugated compounds include carboxylic-acid functionalized π-conjugated compounds, phosphonic acid functionalized π-conjugated compounds, and catechol functionalized π-conjugated compounds. Additionally, π-conjugated compounds may include fullerene moieties, including C₆₀, C₇₀ as well as non-fullerene compounds, such as terthiophene.

As noted above, the electron-transport layer of the devices of the invention include a metal oxide layer and a monolayer that includes an organic material. The combination of the metal oxide and monolayer provides a bilayer that enhances the performance of devices that include these layers. Like the metal oxide component of the bilayer, the monolayer has electron-transporting properties.

In one embodiment, the monolayer is an organic material layer formed on the metal oxide layer. Suitable organic materials include those organic materials having the capacity to form a monolayer on the metal oxide layer and to provide a monolayer having electron-transporting properties. Suitable organic materials include polar organic materials and organic materials having a dipole. In one embodiment, the monolayer is a self-assembled monolayer made from organic materials having the capacity self assemble into a monolayer on the metal oxide layer.

Generally, suitable organic materials include organic compounds having a polar or ionic functional group that interacts with the metal oxide layer. Representative polar or ionic functional groups include carboxylic acid groups (carboxylates, —CO₂⁻), phosphonic acid groups (phosphates, —PO₃²⁻), sulfonic acid groups (sulfonates, —SO₃²⁻), phenolic groups (dihydroxyphenols or catechols), and siloxane groups (Si—O). Representative organic compounds for use in the layer include carboxylic acids, phosphonates, sulfonates, phenols, thiols, and catechols.

In addition to having a polar or ionic group that interacts with the metal oxide layer, these organic compounds have the capacity to form a monolayer (e.g., self-assembled monolayer) on the metal oxide. These compounds have the general formula:

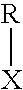

where X is the polar or ionic group as described above and R is an organic group, such as an alkyl, aryl, or heteroaryl group, including substituted alkyl, aryl, and heteroaryl groups. In one embodiment, R includes a fullerene (e.g., C₆₀, C₇₀, C₇₆, or C₈₄) or derivative thereof.

Suitable aliphatic compounds include compounds that include C3-C20 alkyl groups (e.g., R is n-C3-C20 alkyl). Suitable compounds include C3-C20 carboxylic acids and their fluoro-substituted and perfluoro-counterparts. Representative aliphatic carboxylic acids include fatty acids (e.g., n-C10-C20 carboxylic acids) such as decanoic acid, undecanoic acid, dodecanoic acid (lauric acid), tetradecanoic acid, and octadecanoic acid (stearic acid), among others. Representative perfluoroalkyl carboxylic acids include, for example, perfluorotetradecanoic acid.

Suitable aromatic compounds include aryl compounds and heteroaryl compounds.

Representative aryl compounds include those having the formula:

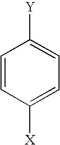

where X is the polar or ionic group as described above and Y is hydrogen or a substituent selected from C1-C6 alkyl (e.g., CH₃), C1-C6 perfluoroalkyl (e.g., CF₃), OC1-C6 alkyl (e.g., OCH₃), amino (e.g., NH₂, NHR, or NR₂, where R is C1-C6 alkyl), thio (e.g., SH or SR, where R is C1-C6 alkyl), halo (e.g., F, Cl, Br, or I), hydroxy, cyano, nitro, halosulfonyl (e.g., SO₂F, SO₂Cl), and fullerene (e.g., C₆₀, C₇₀, C₇₆, or C₈₄) or derivative. In one embodiment, the aryl compound is benzoic acid or derivative (i.e., X is CO₂H and Y is as described above). In another embodiment, the aryl compound is a dicarboxylic acid prepared by esterifying 1,2-dihydroxysuccinic acid with two equivalents of benzoic acid or derivative thereof.

Representative heteroaryl compounds include thiophene compounds such as thiophenecarboxylic acid and its derivatives. A representative thiophenecarboxylic acid derivative is terthiophenecarboxylic acid.

The above organic compounds are particularly useful in photovoltaic devices having inverted architecture. In these devices, the organic material layer (e.g., monolayer or self-assembled monolayer) is positioned between the metal oxide layer and the photovoltaic layer.

For photovoltaic devices having traditional architecture, the organic material layer is positioned between the metal oxide layer and the electron-collecting electrode. In these embodiments, the organic compounds useful in the organic material layer can further include an additional functional group that can interact with or bond to the electrode surface.

Thus, in certain embodiments, the organic compounds useful in the layer are at least bifunctional. In addition to having a polar or ionic group that interacts with the metal oxide layer and have the capacity to form a monolayer (e.g., self-assembled monolayer) on the metal oxide, the compounds further include a functional group that can interact with or bond to the electrode surface. These compounds have the general formula:

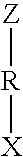

where R and X are as described above and Z is a functional group that interacts with or bonds to the surface of the electron-collecting electrode. Representative functional groups that interact with or bond to the surface of the device's electrode include thiol (e.g., SH or SR, where R is C1-C6 alkyl), amino (e.g., NH₂, NHR, or NR₂, where R is C1-C6 alkyl), hydroxyl, carboxylic acid (carboxylate, —CO₂—), phosphonic acid (phosphate, —PO₃²⁻), sulfonic acid (sulfonate, —SO₃²⁻), phenolic (dihydroxyphenol or catechol), and siloxane (Si—O) groups.

Representative bifunctional organic compounds useful in the electron-transport layer include thiol-substituted carboxylic acids (e.g., HS—(CH₂)ₙ—COOH2, where n is 1-19, such as mercaptoundecanoic acid) and their fluoro- and perfluoro-derivatives (e.g., perfluorotetradecanoic acid), dithioalkanes (e.g., HS—(CH₂)ₙ—SH, where n is 4-20) and their fluoro- and perfluoro-derivatives, alkane dicarboxylates (e.g., HO₂C—(CH₂)ₙ—CO₂H, where n is 2-18), and amino acids (e.g., lysine and H₂N—(CH₂)ₙ—COOH, where n is 1-19).

As will be described further below, the dipole of the monolayer molecules, and the direction of the dipole with relation to the abutting layers, contributes to the enhancement of the device. Additionally, the bonding (e.g., covalent or ionic) to the abutting layers additionally influences the level of device enhancement. The function of a dipolar SAM is to create an interfacial dipole between the metal oxide electron transport layer and the electron-collecting electrode. This dipole will modify the work function of the electrode so that it can align with the valence band of the metal oxide to form an ohmic contact for electron collection, which is a critical condition to achieve a high performance photovoltaic with minimized series resistance and maximized photovoltage.

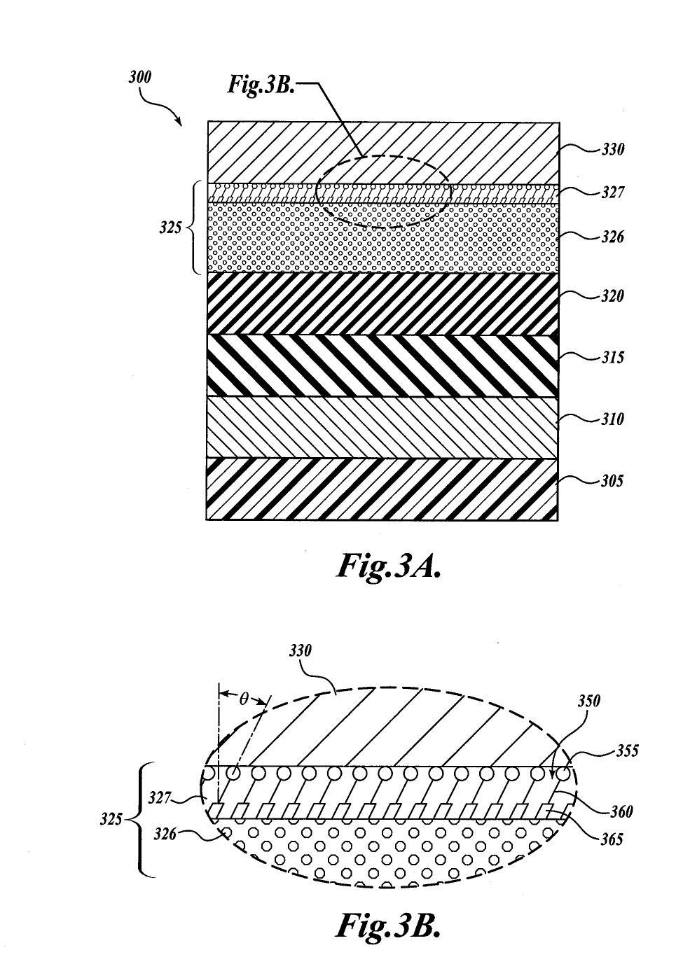

Referring to FIG. 3A, a preferred representative embodiment of a photovoltaic device 300 includes a substrate 305 of glass or plastic. Representative plastic substrates include those made from a polyester, a polyethylene naphthalate, a polyimide, and a polycarbonate. On the substrate 305 is a transparent hole-collecting electrode 310, such as indium-tin oxide.

In one embodiment, a hole-transport layer 315 is provided. Representative hole-transport materials include polymers, such as PEDOT:PSS, or a metal oxide (e.g., oxides of molybdenum, vanadium, silver, nickel, and copper). As illustrated in FIG. 3A, the hole-transport layer 315 is intermediate the hole-collecting electrode 310 and the photovoltaic layer 320.

In this representative embodiment, the photovoltaic layer 320 is a BHJ that includes a polythiophene in compound form with a fullerene-containing molecule, such as PCBM. The ratio of the materials in the BHJ can vary from 1:0.1 to 0.1:1. In a preferred representative embodiment, the ratio of polythiophene to PCBM is 1:0.6.

In this representative embodiment, the enhancement layer 325 includes a zinc oxide nanoparticle layer 326 and a self-assembled monolayer 327 that includes carboxylic-acid-containing compounds. The self-assembled monolayer 327 is intermediate the electron-collecting electrode 330 and the zinc oxide nanoparticle layer 326. The electron-collecting electrode 330 is a metal selected from the group of aluminum, silver, and gold. The self-assembled monolayer 327 modifies the work function of the electron-collecting electrode 330 such that an ohmic contact is formed between the electron-collecting electrode 330 and the photovoltaic layer 320 through the self-assembled monolayer 327 and the zinc oxide nanoparticle layer 326.

Referring to FIG. 3B, a detailed portion of the device 300 illustrated in FIG. 3A is provided. The self-assembled monolayer 327 is illustrated in greater detail and includes monolayer molecules 350 that include a head 355, body 360, and tail 365, with the head 355 abutting the electron-collecting electrode 330 and the tail 365 abutting the zinc oxide nanoparticle layer 326. The tail 365 of the self-assembled molecules 350 optionally interact with the zinc oxide nanoparticle layer 326 (e.g., a bond is formed). Similarly, the head 355 of the self-assembled molecule 350 may interact with the electron-collecting electrode 330, for example, if the head 355 includes a thiol moiety, and the electron-collecting electrode 330 is formed from, for example, gold or silver, then a thiol-metal bond may be formed. The presence of bonding between the self-assembled molecules 350 and the abutting layers 330 and 326 affects the functionality of the monolayer 327 in enhancing electron-transport and modifying the electron-collecting electrode 330 work function to facilitate ohmic contact.

In one embodiment, the monolayer 327 creates an interfacial dipole between the electron-collecting electrode 330 and the zinc oxide layer 326. A variation in the size and polarity of the dipole moment affects the interfacial dipole created by the monolayer 327. Additionally, the concentration of dipolar molecules, e.g., 350, as well as the tilt angle θ of the molecules 350, contribute to the dipole of the monolayer 327, and thus the enhancement of the device provided by the monolayer 327 and the enhancement layer 325.

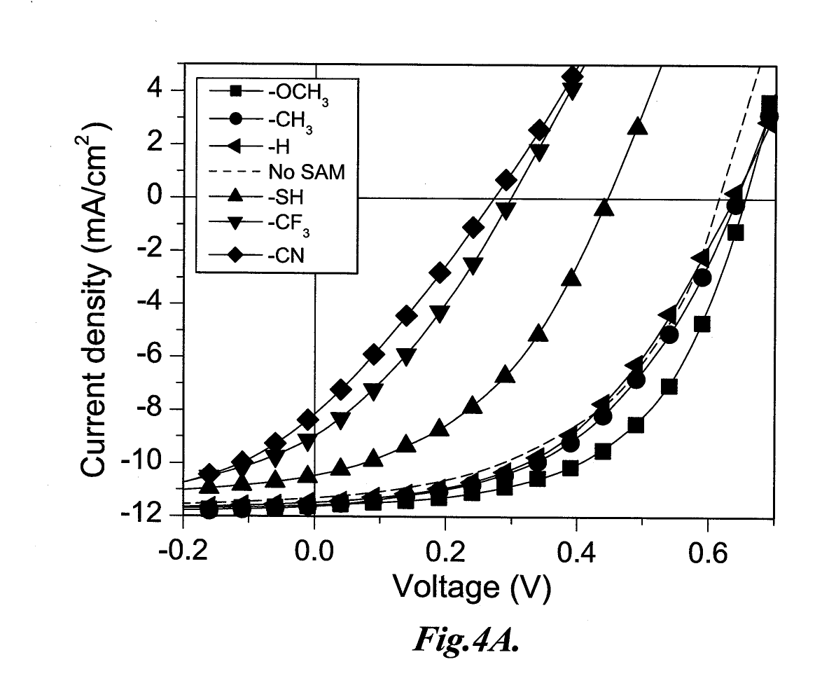

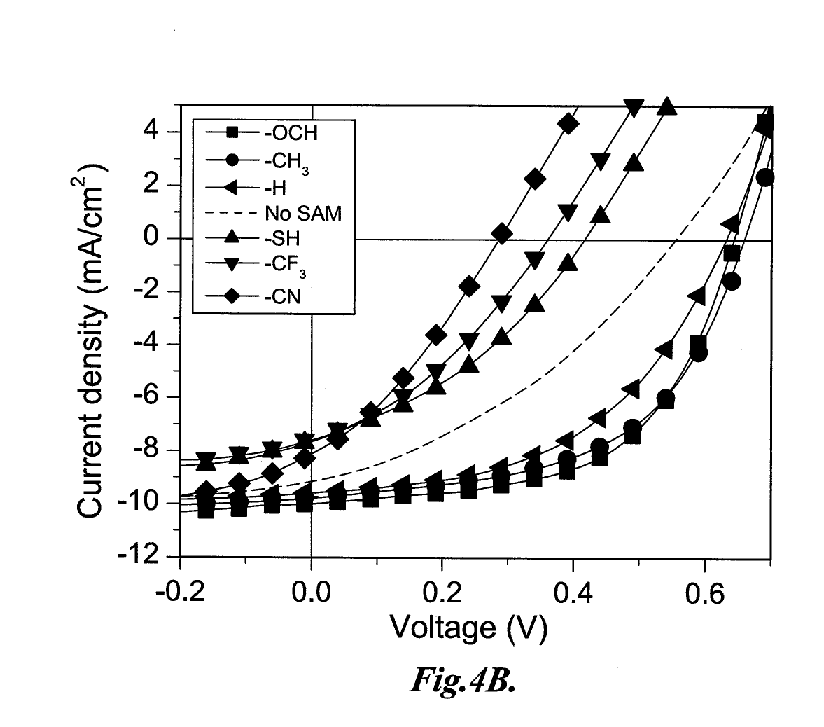

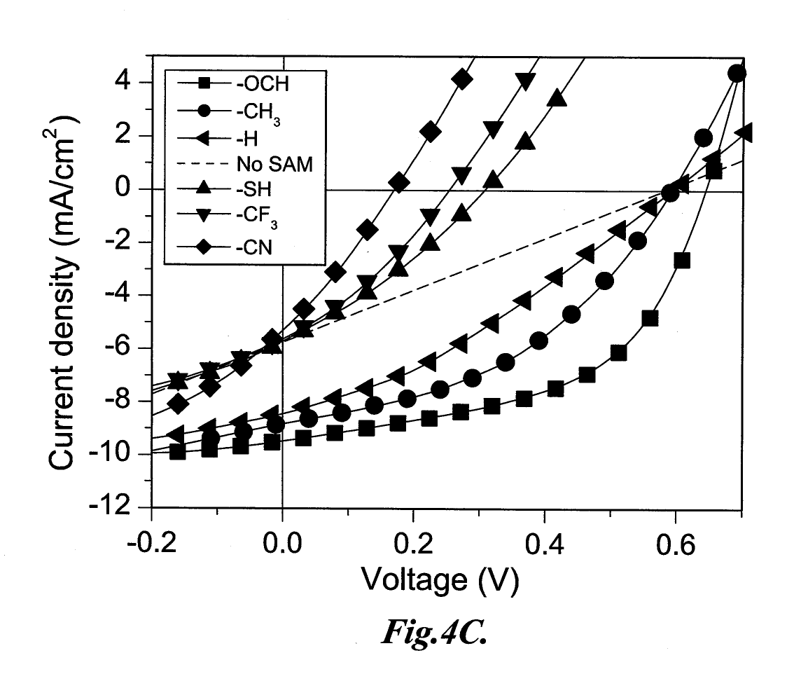

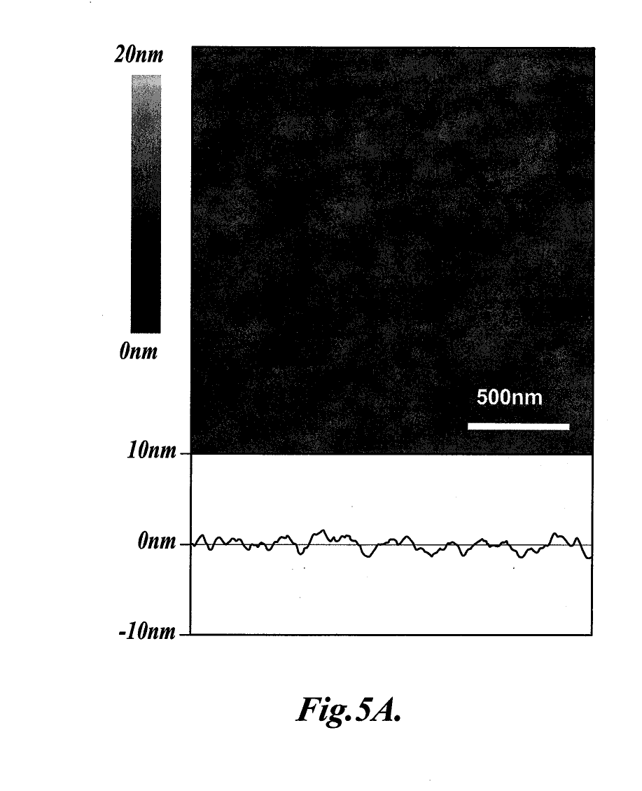

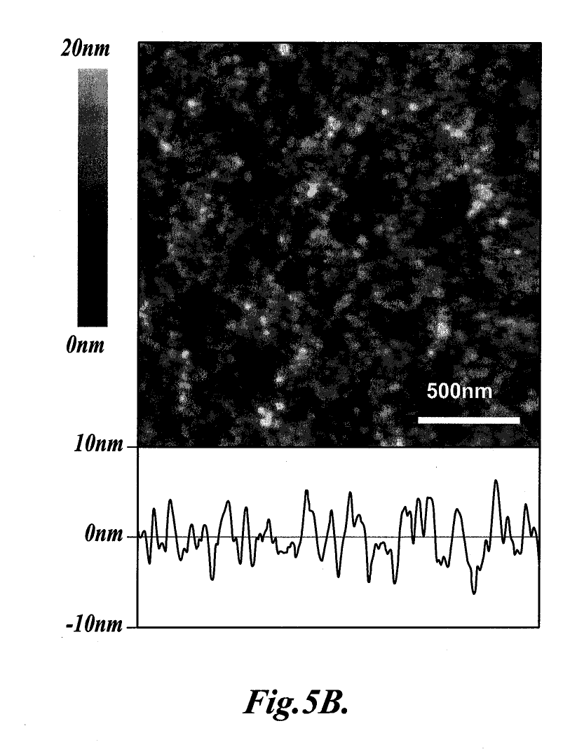

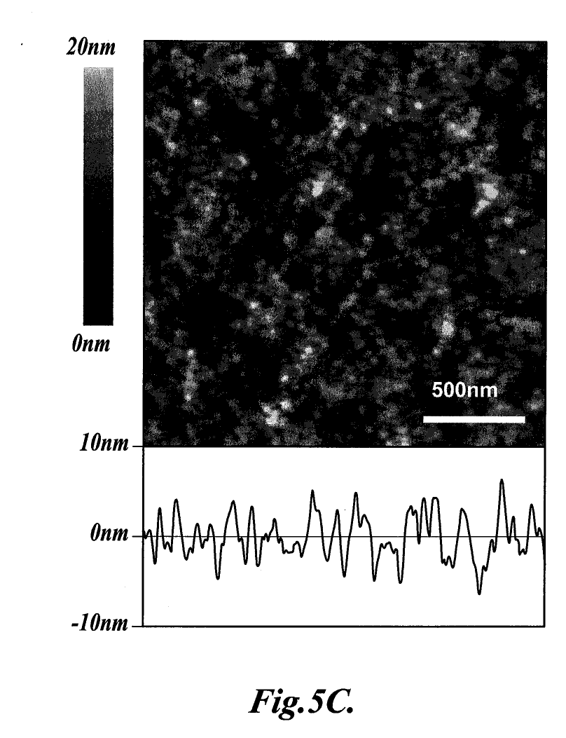

As will be described further in Example 1 and accompanying FIGS. 4A-5C, a series of carboxylic-acid containing π-conjugated molecules were used as exemplary monolayer 327 molecules 350, wherein the carboxylic-acid formed the tail 365 of the molecule 350, phenyl formed the body 360 of the molecule 350, and the head 355 of the molecule 350 was varied to control the dipole of the molecule 350. The gas-phase dipole moment of these benzoic acid derivatives (BA-X) tested in this exemplary embodiment increased in order when substituted with —OCH₃ (−3.9 D)<—CH₃ (−2.9 D)-H (−2.0 D)<—SH (1.5 D)<—CF₃ (2.1 D)<—CN (3.7 D). The devices tested indicate that the molecules containing negative dipoles (—OCH₃, —CH₃, and —H) improve all device characteristics for photovoltaic devices fabricated using the monolayer 327 containing these molecules 350. A maximum PCE of 4.21% was achieved for the most negative dipole (—OCH₃) tested.

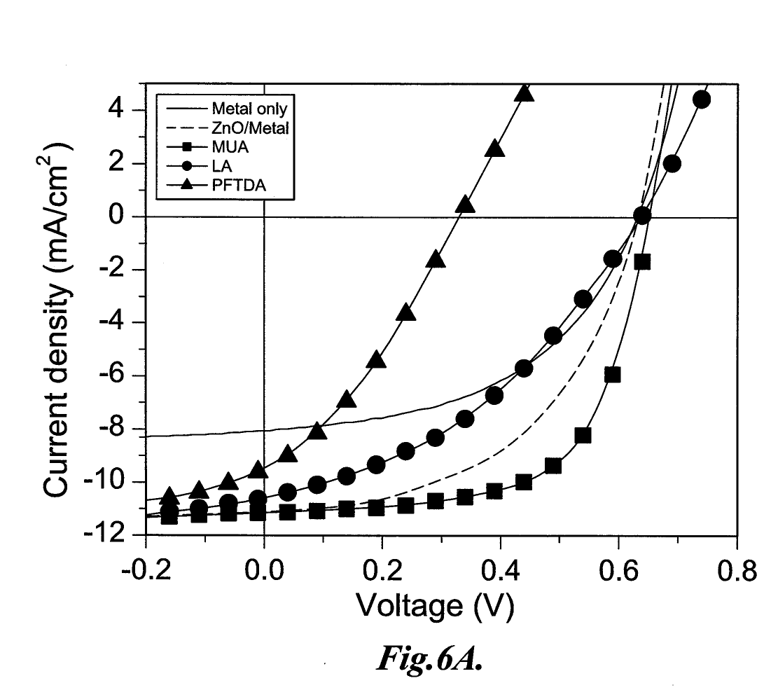

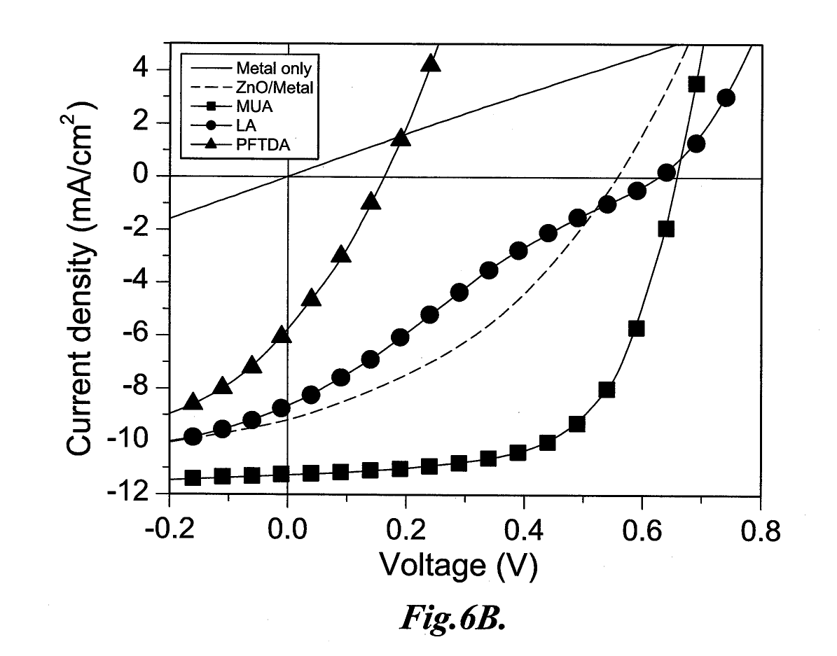

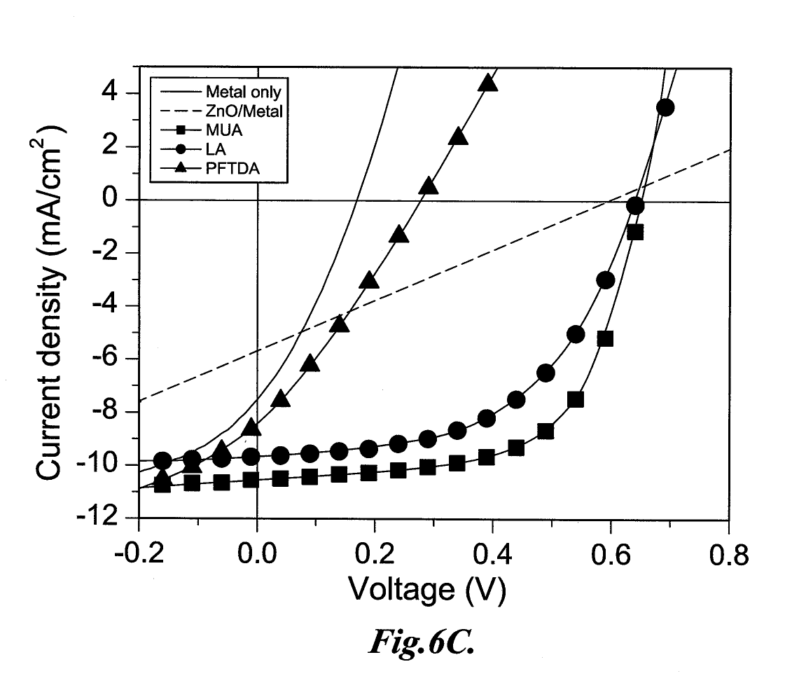

Example 2 and accompanying FIGS. 6A-6C describe the results of experimental testing of a series of monolayer materials in PV devices. A series of saturated aliphatic and fluorinated-aliphatic molecules were tested in PV devices and devices made using a thiol-terminated aliphatic carboxylic-acid show an improvement over non-monolayer containing devices of up to six times with regard to power-conversion efficiency (maximum PCE of 4.6%). A portion of the improvement in device performances with thiol-terminated monolayers can be attributed to the bonding between the thiol moiety and the metal contacts, in addition to the dipolar enhancement provided by the monolayer.

The use of an enhancement layer that includes both a metal oxide layer and a monolayer has the potential to produce high-efficiency photovoltaic devices. Without the monolayer, the work function of an electrode (e.g., electron-collecting electrode) cannot be modified to produce ohmic contact with the photovoltaic layer, but PV devices that include only a metal oxide electron-transport layer still provide enhanced device properties. In one aspect, a photovoltaic device is provided that includes zinc oxide nanoparticles as an electron enhancement layer. ZnO NPs have a high electron mobility (0.066 cm²/V·s) and provide an increased surface area and a unique morphology at the interface of the electron-transport layer with the photovoltaic layer and electron-collecting electrode. As described in Example 2 (particularly Table 2) and Example 4 (for inverted devices), a ZnO NP electron-transport layer without an SAM improves the PCE of devices with Al, Ag, and Au electrodes.

In another aspect, a method for fabricating a photovoltaic device including an enhancement layer is provided. In one embodiment, the method includes forming a photovoltaic layer on a hole-collecting electrode, forming a metal oxide layer on the photovoltaic layer, forming a monolayer on the metal oxide layer, and forming an electron-collecting electrode on the monolayer.

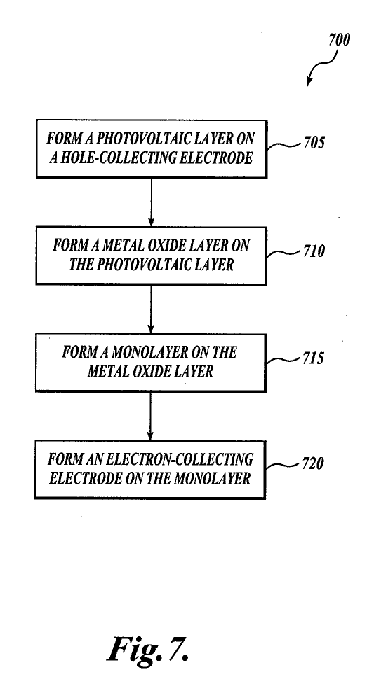

Referring to FIG. 7, a flowchart is provided illustrating the method 700, which begins with a step 705 that includes forming a photovoltaic layer on a hole-collecting electrode. The method continues with a step 710 of forming a metal oxide layer on the photovoltaic layer. The method 700 continues with a step 715 of forming a monolayer on the metal oxide layer. The method 700 concludes with a step 720 of forming an electron-collecting electrode on the monolayer.

The method 700 optionally includes providing a substrate (not pictured) abutting one of the electrodes. In a representative embodiment where the hole-collecting electrode is a transparent conductor, such as ITO, such a transparent conductor is typically formed on a transparent substrate such as glass or plastic.

Additionally, the method 700 can be optionally modified to include forming a hole-transport layer on the hole-collecting electrode prior to the step 705 of forming a photovoltaic layer. In this embodiment, the hole-transport layer is formed using a technique such as spin coating, drop coating, blade coating, spray coating, screen printing, inkjet printing, and vapor deposition. The After the hole-transport layer is formed, the method 800 proceeds with forming the photovoltaic layer on the hole-transport layer.

It will be appreciated that the liquid-based techniques for forming a layer of a device described herein (e.g., spin coating) typically first form a layer that includes a solid portion mixed with residual liquid. The residual liquid is then removed by heating the layer, applying a vacuum, or both, to provide a layer of the solid (e.g., a hole-transport layer)

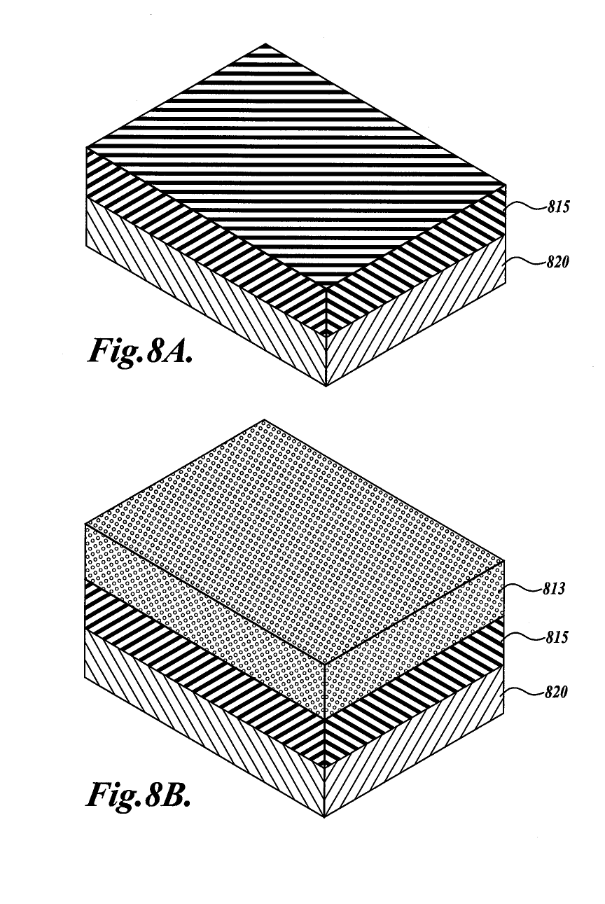

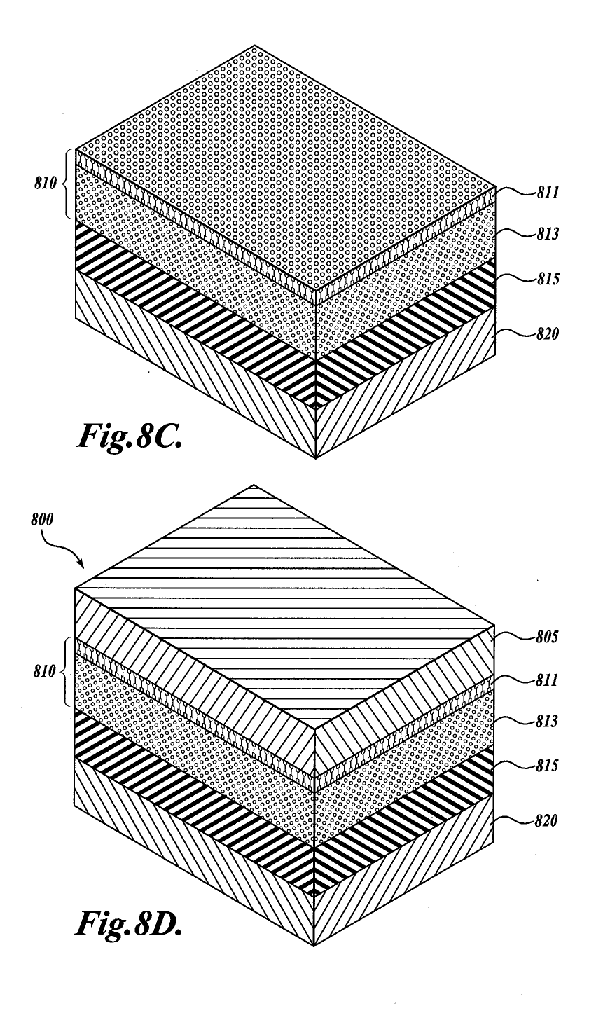

The fabrication method 700 described above may be more readily understood with reference to FIGS. 8A-8D, illustrating the sequential deposition of layers to form a photovoltaic device. In the exemplary embodiment illustrated in FIGS. 8A-8D, the deposited layers of the device are coextensive and contiguous. Thus, in one embodiment, the layers of the device are contiguous and substantially coextensive in area.

Referring to FIG. 8A, a photovoltaic layer 815 is formed on a hole-collecting electrode 820. Representative methods for forming the photovoltaic layer include spin coating, drop coating, blade coating, spray coating, screen printing, inkjet printing, and vapor deposition. The hole-collecting electrode 820 may be a continuous conductive layer (as illustrated) or a grid, as will be described further below.

Referring to FIG. 8B, a metal oxide layer 813 is formed on the photovoltaic layer 815. Representative methods for forming the metal oxide layer 813 include spin coating, drop coating, blade coating, spray coating, screen printing, inkjet printing, vapor deposition, and sol-gel techniques, such as depositing a sol-gel and annealing the deposited sol-gel to provide a hardened metal oxide film. In a preferred embodiment, the metal oxide film 813 is deposited by spin coating nanoparticles of the metal oxide (e.g., zinc oxide nanoparticles).

Referring to FIG. 8C, a monolayer 811 is formed on the metal oxide layer 213 to form an enhancement layer 810. Representative techniques for forming the monolayer include spin coating, drop coating, blade coating, spray coating, screen printing, inkjet printing, vapor deposition, and immersion (i.e., immersing the metal oxide layer in a solution containing the monolayer molecules or their precursors). In a representative embodiment, the monolayer includes a carboxylic-acid group that preferentially binds to the metal oxide layer 813 to form a covalent bond.

The fabrication of a photovoltaic device 800 is completed with the formation of an electron-collecting electrode 805, as illustrated in FIG. 8D. Representative techniques for depositing such electrodes are known to those of skill in the art, and include liquid based techniques, such as spin coating, drop coating, blade coating, spray coating, screen printing, inkjet printing, and vapor deposition; as well as vacuum techniques, such as sputtering and electron-beam deposition.

The hole-collecting electrode and electron-collecting electrode are optionally in the form of a grid. In a preferred embodiment, the grid is a metal grid. Representative grid metals include aluminum, copper, silver, gold, zinc, and titanium. There are several methods useful to produce a metal grid on either glass or plastic substrate.

Micro-contact printing followed by wet-chemical etching method can be used to form metal grids with a resolution of about 5 μm. First, a metal film is deposited on glass or plastic substrate by thermal evaporation. A thiolated SAM, which acts as a chemical resist, is then patterned on the metal film by micro-contact printing using a patterned elastomer stamp. The SAM-patterned substrate is then immersed in a suitable wet-chemical etching bath to etch the unpatterned areas of the metal film. Finally, the SAM is removed by oxygen plasma to produce a clean metal grid.

The metal grid can also be formed by direct thermal evaporation of metal onto a substrate through suitable shadow masks. The resolution of a grid deposited by shadow mask will typically be limited to around 50 μm.

Inkjet printing of metal nanoparticle “ink” can also be used to form metal grids. A grid pattern composed of the nanoparticles can be directly printed on a substrate. After the printing of the nanoparticles, the substrate is slightly heated to convert the nanoparticle ink into a conductive metal film.

It will be appreciated that the previously described photovoltaic devices (e.g., device 200) are traditional device architectures because the hole-collecting electrode (e.g., 220) is transparent (e.g., ITO), and the electron-collecting electrode (e.g., 205) is a metal (e.g., aluminum). Through the use of an enhancement layer, as described above, an inverted device architecture is possible where ITO is used as the electron-collecting electrode. Thus, in another aspect, a method for making an inverted photovoltaic device is provided. In one embodiment, the method includes forming a metal oxide layer on an electron-collecting electrode, forming a monolayer on the metal oxide layer, forming a photovoltaic layer on the monolayer, and forming a hole-collecting electrode on the photovoltaic layer.

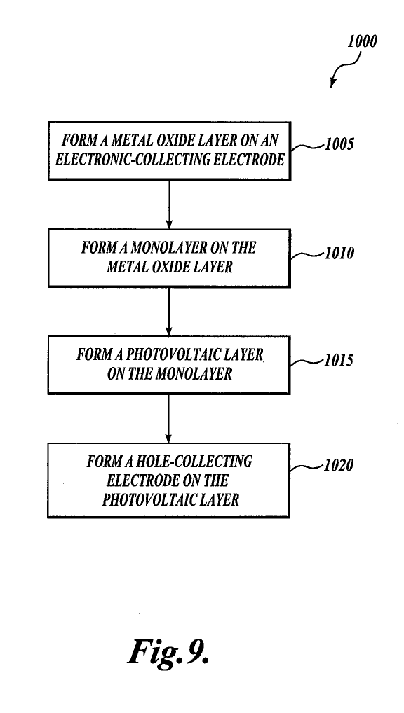

FIG. 9 illustrates a flowchart for the fabrication of an inverted photovoltaic device. The method 1000 begins with a step 1005 of forming a metal oxide layer on an electron-collecting electrode. The method 1000 continues with a step 1010 of forming a monolayer on the metal oxide layer. The method 1000 continues with a step 1015 of forming a photovoltaic layer on the monolayer. The method 1000 concludes with a step 1020 of forming a hole-collecting electrode on the photovoltaic layer.

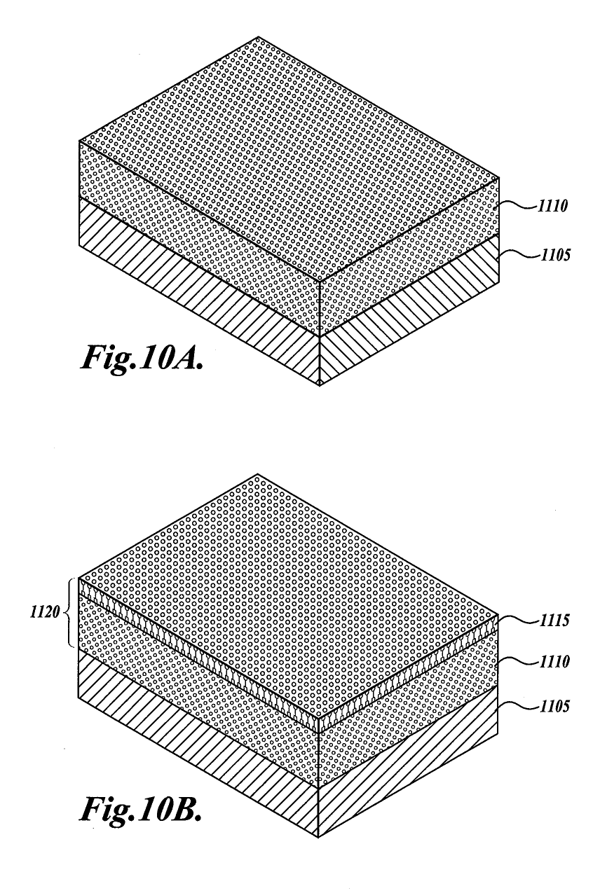

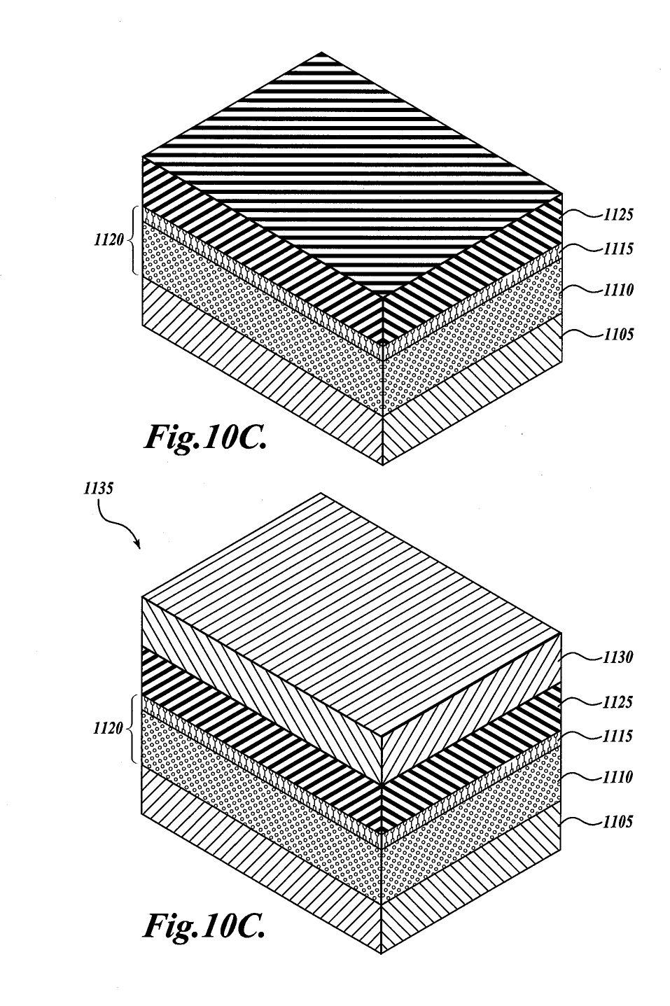

The fabrication of inverted devices may be more readily understood with reference to FIGS. 10A-10D, illustrating the formation of the layers of an inverted photovoltaic device. Referring to FIG. 10A, a metal oxide layer 1110 is formed on an electron-collecting electrode 1105. Representative techniques for forming metal oxide layers are described above.

Referring to FIG. 10B, a monolayer 1115 is formed on the metal oxide layer 1110, to form an enhancement layer 1120. Representative techniques for forming monolayers 1115 are described above.

Referring to FIG. 10C, a photovoltaic layer 1125 is formed on the monolayer 1115. Representative techniques for forming photovoltaic layers are described above.

Referring to FIG. 10D, an inverted photovoltaic device 1135 is completed by the formation of a hole-collecting electrode 1130 on the photovoltaic layer 1125 such that the completed device 1135 includes an electron-collecting electrode 1105, a metal oxide layer 1110, a monolayer 1115, a photovoltaic layer 1125, and a hole-collecting electrode 1130.

Such an inverted device 1135 allows a transparent conductor, such as ITO, to be used as an electron-collecting electrode 1105, whereas ITO is typically only used as a hole-collecting electrode because of the size of its work function in relation to most metals. The presence of the enhancement layer 1120 in the device 1135 allows for the energetics of the device to be modified such that the metal oxide layer 1110 acts as an enhancement to the electron-collecting electrode 1105. The enhancement layer 1120 allows the electron-collecting electrode 1105 to be made of a material having a higher work function than would typically be found in an electron-collecting electrode. The monolayer 1211 further enhances the device 1135 by reducing series resistance by passivating inorganic surface trap states as well as enhancing electronic coupling between the metal oxide layer 1110 and the photovoltaic layer 1125.

The fabrication and characterization of inverted photovoltaic devices (e.g., 1135) are described in further detail in Example 3 (electron-transport layer of ZnO NPs modified with SAMs), Example 4 (electron-transport layer of ZnO NPs with no SAMs), and Example 5 (electron-transport layer of titanium oxide layer modified with SAMs).

Both traditional and inverted photovoltaic devices with an enhancement layer can be fabricated entirely in an oxygen-containing environment (e.g., ambient conditions) such that their fabrication is less expensive than those of traditional photovoltaic devices, which require an inert atmosphere and typically vacuum conditions for one or more fabrication steps. Devices may also be fabricated in an oxygen-free environment, which is how typical prior art devices are fabricated due to the sensitivity of particular materials to oxygen.

The previously described devices are particularly useful for generating electrical current, thus, in another aspect, a method for producing electrical current from electromagnetic radiation is provided. In one embodiment, the method includes exposing the photovoltaic layer of a photovoltaic device of the invention to electromagnetic radiation of a wavelength sufficient to generate electrons and holes in the photovoltaic layer.

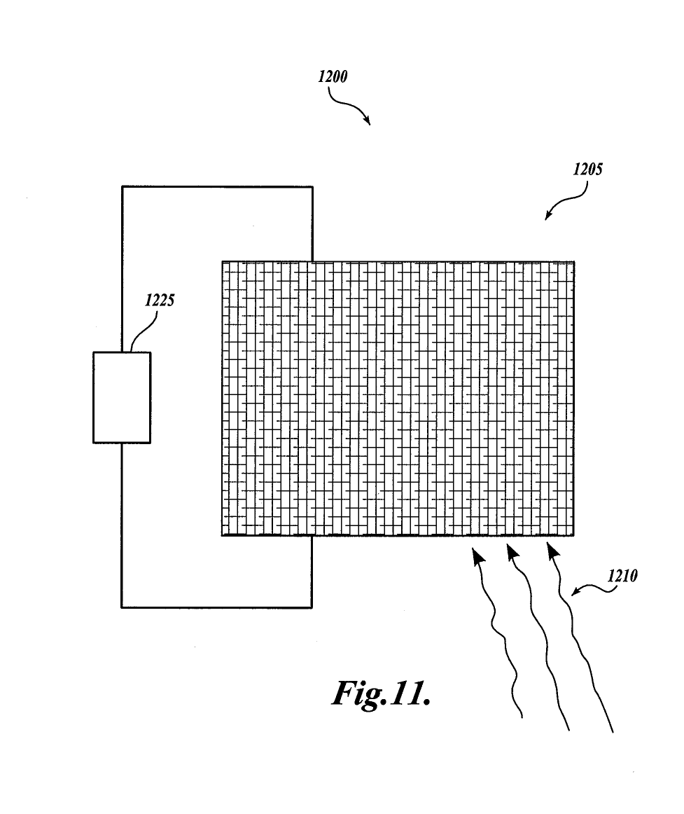

Referring to FIG. 11, a system for generating electrical current 1200 includes a photovoltaic device of the invention 1205. The device 1205 is illustrated as irradiated by light 1210 of a particular frequency, or frequencies, such that free carriers are generated in the photovoltaic layer of the device 1205. A device in need of electrical current 1225 is in electrical communication with the device 1205 (e.g., electrical contact is made with the electron-collecting electrode and hole-collecting electrode) such that the generation of electrical current by the device 1200 provides such electrical current to the device in need of electrical current 1225.

In a representative embodiment, the device in need of electrical current 1225 is a battery or an electrical circuit.

While photovoltaic devices have been described above, it will be appreciated that the enhancement layer is also useful for improving other optoelectronic devices. In another aspect, an optoelectronic device is provided that includes the enhancement layer. In one embodiment, the optoelectronic device includes an anode, an active layer, a cathode, and an electron-transport layer that includes a metal oxide and a monolayer intermediate the active layer and at least one of the anode and cathode.

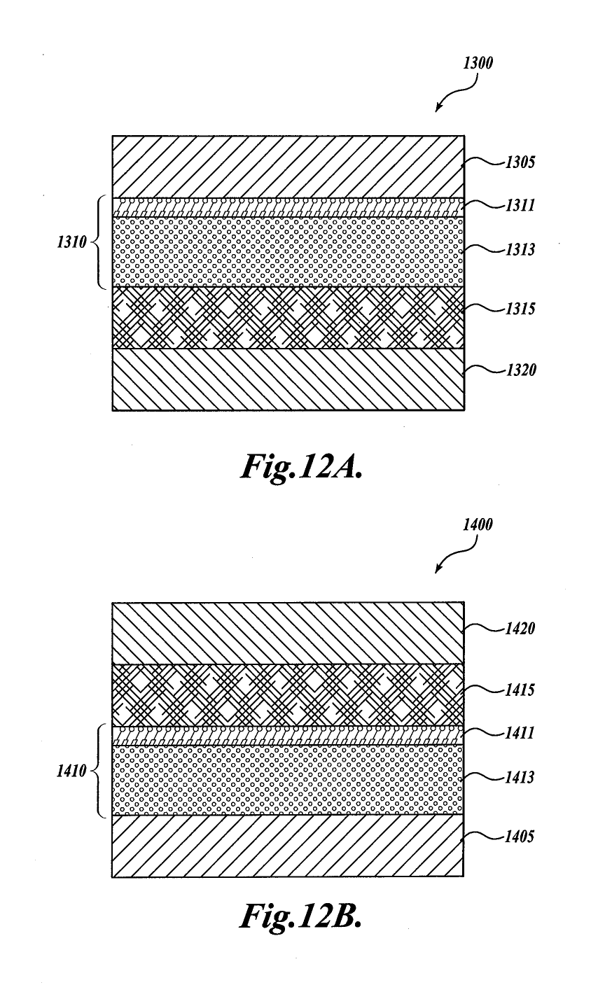

The optoelectronic device may be more readily understood with reference to FIG. 12, where an optoelectronic device 1300 is illustrated. The device 1300 includes an anode 1320, an active layer 1315, a metal oxide layer 1313, a monolayer 1311, and a cathode 1305. As previously described, photovoltaic devices (e.g., 200) are optoelectronic devices, but other optoelectronic devices may be improved using the metal oxide-monolayer enhancement layer 1310 provided. Those of skill in the art will appreciate that photovoltaic devices are typically similar to organic light-emitting devices (OLED) in structure. In operation, the two types of devices are essentially operated in reverse of each other. Photovoltaic devices create electrical current from light, and OLEDs create light from electrical current.

The provided optoelectronic device includes an enhancement layer 1310. The active layer 1315 partially defines the function of the device, such that a photovoltaic material as the active layer 1315 will result in the device operating as a photovoltaic device, whereas a light-emitting material (e.g., a polyfluorene) will result in the device being an OLED. It will also be appreciated that the two types of devices are not mutually exclusive because some materials may be useful as both a photovoltaic material and a light-emitting material. The enhancement layer 1310 enhances the efficiency of passing charge carriers between the active layer 1315 and a cathode 1305. Both PV and OLED devices, as well as other devices known to those of skill in the art that incorporate electron-transporting materials, will be improved by the enhancement layer provided herein.

In another aspect, a photovoltaic device including an enhancement layer is provided. In one embodiment, the device essentially includes a hole-collecting electrode, a photovoltaic layer, an electron-collecting electrode, and an electron-transport layer that includes a metal oxide and a monolayer, located intermediate the electron-collecting electrode and the photovoltaic layer. The device optionally includes a hole-transport layer and/or a substrate.

The following examples are provided for the purpose of illustrating, not limiting, the invention.

### EXAMPLES

Material preparation: All monolayer molecules were purchased from Aldrich unless specified otherwise.

Zinc oxide (ZnO) nanoparticles were prepared based on a procedure adapted from Beek et al., J. Phys. Chem. B 2005, 109, 9505, incorporated herein by reference in its entirety. Zinc acetate dihydrate (Scholar Chemistry >99%, 2.95 g) was dissolved in methanol (125 mL) at 60° C. A KOH (EMD, 85%, 1.48 g) solution was prepared by dissolving KOH in methanol (65 mL). The KOH solution was added to the zinc acetate dihydrate solution dropwise in 10 min under vigorous stirring. The solution temperature was held at 60° C. and stirred for 2.5 h, after which temperature and stirring were removed to allow particles to precipitate for an additional 2 h. The particles were cleaned by centrifugation of the solution and washed with methanol. The centrifugation and washing was repeated twice. The washed nanoparticles were dissolved in 1-butanol to give a concentration of 30 mg/mL.

Device characterization: AFM images under tapping mode were acquired on a Veeco multimode AFM with a Nanoscope III controller. The AFM images were taken from actual devices fabricated for measurement of solar performance. The I-V characteristics of PV devices were tested in air using a Keithley 2400 source measurement unit and an Oriel Xenon lamp (450 W) coupled with an AM 1.5 filter was used as the light source. The light intensity was calibrated with a calibrated standard silicon solar cell with a KG5 filter which is traced to the National Renewable Energy Laboratory and a light intensity of a 100 mW/cm² was used in all the measurements.

### Example 1

### Photovoltaic Devices Having Zinc Oxide Nanoparticle and Benzoic Acid Monolayer Electron-Transporting Layers

This example describes a solution-based processing method for fabricating PV devices that include an SAM-modified ZnO/metal bilayer electron-collecting electrode. A series of conjugated carboxylic-acid SAMs with various dipoles was used to tune the contact property between the ZnO layer and three different metal electron-collecting electrodes: Al, Ag, and Au. Self-assembled molecules used in this example include para-substituted benzoic-acid (BA-X) molecules where X is: —OCH₃, —CH₃, —H, —SH, —CF₃, or —CN. The devices have large efficiencies, even when high work-function metals, such as Ag and Au, were used as electron-collecting electrodes.

The structure of the PV devices used in this Example are illustrated in FIG. 3A. Device fabrication began with ITO-coated glass substrates (15Ω/□) cleaned in an ultrasonic bath with detergent, DI water, acetone, and isopropyl alcohol and then dried under a N₂ stream. The substrates were then treated with oxygen plasma for 10 min. A 50 nm hole-transport layer of PEDOT:PSS (Bayer AG) was then spin-coated on the substrate from an aqueous solution followed by annealing the film at 140° C. for 10 min in air. The substrates were then transferred into an argon-filled glove box. A chlorobenzene solution comprising a P3HT (25 mg mL⁻¹) and PCBM (15 mg mL⁻¹) was then spin-coated on the PEDOT:PSS layer to achieve a 200 nm thick BHJ photovoltaic layer. The P3HT:PCBM film was then annealed on a hot plate inside the glove box at 160° C. for 10 min. After the substrate was cooled to room temperature, a 40-50 nm thin film of ZnO nanoparticles (NPs) was spin-coated on the photovoltaic layer from 1-butanol after filtering through a 0.2 μm PTFE filter. After the solvent dried, the ZnO nanoparticle film was insoluble in alcoholic solvents. The self-assembled molecules were then deposited on the ZnO surface using a two-step spin-coating process. First, 1 mM of the molecules in ethanol was spin-coated on the ZnO film, a monolayer of the molecules was formed through the chemical bonding between carboxylic-acid and ZnO. To remove physically adsorbed molecules, a second spin-coating using pure ethanol was applied. Finally, the substrates were transferred to a vacuum chamber installed inside the glove box. Subsequently the device was pumped down in vacuum (1×10⁻⁶ Torr) and 100 nm of metal film was deposited by evaporation on top of the device at a slow deposition rate of 0.5 Å/s to minimize the potential damage of the self-assembled monolayer.

The effect of the BA-X SAMs on PV device performance for electron-collecting electrodes of Al, Ag, and Au in PV devices are summarized in FIGS. 4A (Al), 4B (Ag), and 4C (Au) and Table 1.

The impact of ZnO on the performance of BHJ PV devices with different metal electron-transporting electrodes was investigated. In BHJ PV devices, the maximum available voltage depends on the difference of the quasi Fermi levels of the photoinduced holes on the p-doped donor and the photoinduced electrons on the n-doped acceptor. This result is obtained only if ideal contacts (ohmic) are formed at both negative and positive electrodes when their work-functions are matched with the LUMO of the acceptor and the HOMO of the donor, respectively. When a barrier contact (or Schottky contact) is formed at either side or both sides of the semiconductor/electrode interface, the V_{oc} will be reduced. According to the metal-insulator-metal model, the magnitude of this reduction is determined by the static internal electric field across the device, which is a result from the difference in the work-functions of the electrodes. In the case of a ZnO electron-transport layer inserted between the photovoltaic and electron-collecting electrode, as the valence band of ZnO (4.4 eV) is very close to the LUMO of PCBM (4.3 eV) and efficient electron transfer has been reported at the PCBM/ZnO interface, a negligible contact loss at that interface can be assumed. As a result, the nature of the contact at the ZnO/metal interface contributes to the performance of the device when utilizing a ZnO layer.

Devices having Al as an electron-collecting electrode and a ZnO layer demonstrate an increase in J_{sc} and Rₚ and a decrease in Rₛ, leading to an improvement of power-conversion efficiency (PCE) from 2.42% to 3.16%. The increase in J_{sc} may be attributed to the optical spacer effect from the ZnO layer, resulting in an enhancement of the optical electric field distribution in the active layer for better light harvesting, or the decrease of contact resistance with the introduction of the ZnO layer. In addition to efficient charge transfer from PCBM to ZnO and its hole blocking property, the ZnO layer also shields the photovoltaic layer from being physically damaged and chemically degraded during the metal deposition. This results in an improvement on both the parallel and series resistance.

Using a Ag layer as the electron-collecting electrode did not produce any diode characteristic although the reported work-function of Ag (4.4 to 4.65 eV) is close to that of Al (4.3 eV). The result is not surprising because Ag may react with sulfur in P3HT or be oxidized during the thermal deposition process or exposure to oxygen, making the effective work function of 5.0 eV, which is favorable for hole collection instead of electron collection.

Devices with an Au electrode have poor device performance due to the mismatch between the work-function of Au (5.1 eV) and the LUMO of PCBM (4.3 eV), which limits the build up of V_{oc} and forms a contact with high resistance. Unlike the formation of ohmic contact between ZnO and Al, Ag and Au usually form Schottky contact with ZnO with various barrier heights depending on the type of interactions between metal and the surface of ZnO. The poor electrical contact between ZnO/Ag and ZnO/Au significantly affects the device performance. Compared to devices with ZnO/Al as the electron-collecting electrode, the devices with ZnO/Ag or ZnO/Au as the electron-collecting electrodes had lower V_{oc} of 0.54V and 0.57V, respectively. The high Rₛ and poor rectification in the case of using ZnO/Au electron-collecting electrode resulted in devices with PCE of only 0.72%. Devices with ZnO/Ag electron-collecting electrode showed better performance with PCE of 1.75%.

To investigate the effect of SAM-modified ZnO/metal electron-collecting electrodes on the performance of PV devices, the contact properties of the ZnO/metal junctions were tuned by forming an interfacial dipole with a series of para-substituted benzoic acids (BA) with various dipole moments. The molecules were self-assembled into roughly one monolayer thickness on the surface of ZnO through spin casting. FIG. 5A is an AFM micrograph illustrating the topography of a thermally annealed BHJ layer of P3HT/PCBM. FIG. 5B is a micrograph of the ZnO NP layer deposited on the photovoltaic layer. FIG. 5C is a micrograph of SAM-modified ZnO NPs, with a BA-OCH₃ monolayer. Formation of SAMs was confirmed by the results from contact angle measurements after surface modification.

The SAMs modify the work-function of the electron-collecting electrode. When the work-function of the modified electrode matches with the conduction band (CB) of ZnO, ohmic contact is formed and the internal electric field across the device is optimized. Therefore, the magnitude of the open-circuit voltage will approach V_{oc}, which is the maximum achievable photovoltage in a bulk-heterojunction photovoltaic device. The gas-phase dipole moment of the benzoic acid derivatives increased in order when substituted with —OCH₃ (−3.9 D)<—CH₃ (−2.9 D)-H (−2.0 D)<—SH (1.5 D)<—CF₃ (2.1 D)<—CN (3.7 D).

Because the ZnO/metal bilayer electrode is responsible for electron collection, a dipolar monolayer with a net dipole directed towards the ZnO layer will reduce the band offset between the CB of ZnO and the work function of the electrode to achieve ohmic contact to obtain a maximized V_{oc}. Devices with a net dipole directed away from the ZnO resulted in an increase of Schottky barrier, which is expected to decrease the device performance.

When compared to the unmodified devices, devices modified with molecules containing negative dipole (—OCH₃, —CH₃, —H) show improvement in all the J-V characteristics including J_{sc}, V_{oc} and FF, resulted in an overall increase in PCE. While devices modified with molecules containing positive dipole (—SH, —CF₃, —CN) show an opposite effect. The observed result seems to contradict predicted because an interfacial dipole directed away from the ZnO surface should be formed with a monolayer of molecules containing negative dipole (e.g., BA-OCH₃). This dipolar layer will lead to an increase in the Schottky barrier and lower the device efficiency. Similarly, a molecular monolayer containing positive dipole (e.g., BA-CN) will generate an interfacial dipole directed towards the ZnO surface, leading to an ohmic contact between ZnO/metal with improved device performance.

The discrepancy can be explained because the Schottky barrier in a ZnO/SAM/Au diode is reduced when an electron-donating group such as —OCH₃ is in contact with Au while the Schottky barrier increased when an electron—withdrawing group such as —CN is in contact with Au. The reason is that when the dipolar molecules are directly in contact with the metal, the intimate metal-molecule contact at the interface makes direct metal-molecule polarization possible, leading to a trend in molecular dipole at the interface to be opposite to that at a free surface or polymeric materials). As a result, the net interfacial dipole across the ZnO/BA-X/metal junction when X═OCH₃, —CH₃, —H and X═SH, —CF₃, —CN will be directed towards and away from the ZnO, respectively.

FIG. 4A is a graph of J-V curves of the devices using ZnO/BA-X/Al as the electron-collecting electrode under AM1.5 illumination. Compared to devices using ZnO/Al as the electron-collecting electrode, those modified with SAMs containing negative dipole (X═OCH₃, —CH₃, —H) has a positive effect on the device performance, including an increase in V_{oc} and J_{sc} and a reduction of Rₛ. Among those devices, the one modified with BA-OCH₃, which has the most negative magnitude of dipole moment among those tested, has the most significant improvement in performance with V_{oc}=0.65 V, J_{sc}=11.61 mA/cm², FF=0.55 and PCE=4.21%. Devices modified with molecules containing positive dipole (X═SH, —CF₃, —CN) show a successive decrease in device performance upon increasing dipole moment. The result is the consequence of the interfacial dipole effect, shifting the work function of Al away from the CB of ZnO, leading to an increase in the Schottky barrier between the ZnO and the metal, which limits the V_{oc} and causes poor diode characteristics.

The use of an interfacial dipole to manipulate the contact in ZnO/Ag and ZnO/Au junctions has a large effect because devices not modified with a SAM have Schottky contacts, making them ineffective electron-collecting electrodes for PV devices. Similar to the result found in the ZnO/Al system, interfacial modification of the ZnO/Ag and ZnO/Au interfaces using BA-OCH₃ shows the most significant improvement in device performance due to the large interfacial dipole effect, which efficiently shifts the work-functions of Ag and Au close to the CB of ZnO to form an effective junction for electron collection. The dependence of the strength of interfacial dipole on the degree of the work-function offset shows clearly in the case of ZnO/Au system (FIG. 4C and Table 1), which has the largest energy difference between the CB of ZnO and the work-function of the metal. Modification of this system using SAMs with a sequential increase in negative dipole moment from BA-H to BA-CH₃ to BA-OCH₃ shows gradual improvement in diode characteristics with PCE of 1.6%, 2.2%, and 3.2%, respectively, which corresponds to about a 2-fold, 3-fold and 4-fold increase in performance compared devices not modified with an SAM.

TABLE 1
Device performance of photovoltaic devices with
ZnO/benzoic acid-based SAM/metal electron-collecting
electrodes, averaged over ten devices.

| Electron- | | | | | | |
|---|---|---|---|---|---|---|
| collecting | | | | | Rₚ | Rₛ |
| electrode | Voc | J_{sc} | | PCE | (Ω · | (Ω · |
| Configuration | (V) | (mA/cm²) | FF | (%) | cm²) | cm²) |
| ZnO/BA-OCH₃/Al | 0.65 | 11.61 | 0.55 | 4.21 | 648.8 | 1.5 |
| ZnO/BA-CH₃/Al | 0.64 | 11.63 | 0.49 | 3.63 | 438.0 | 2.1 |
| ZnO/BA-H/Al | 0.64 | 11.46 | 0.48 | 3.48 | 583.3 | 2.2 |
| ZnO/Al | 0.60 | 11.29 | 0.47 | 3.16 | 392.5 | 3.1 |
| ZnO/BA-SH/Al | 0.45 | 10.44 | 0.42 | 1.95 | 184.7 | 13.3 |
| ZnO/BA-CF₃/Al | 0.30 | 8.97 | 0.31 | 0.84 | 64.1 | 24.2 |
| ZnO/BA-CN/Al | 0.27 | 8.15 | 0.28 | 0.62 | 47.2 | 14.4 |
| ZnO/BA-OCH₃/Ag | 0.65 | 9.97 | 0.57 | 3.65 | 628.0 | 2.1 |
| ZnO/BA-CH₃/Ag | 0.66 | 9.73 | 0.54 | 3.49 | 483.1 | 2.4 |
| ZnO/BA-H/Ag | 0.63 | 9.57 | 0.49 | 2.98 | 523.3 | 4.2 |
| ZnO/Ag | 0.54 | 8.75 | 0.37 | 1.75 | 174.4 | 9.6 |
| ZnO/BA-SH/Ag | 0.42 | 7.61 | 0.36 | 1.14 | 130.8 | 24.5 |
| ZnO/BA-CF₃/Ag | 0.36 | 7.52 | 0.35 | 0.94 | 128.2 | 28.8 |
| ZnO/BA-CN/Ag | 0.28 | 8.18 | 0.32 | 0.74 | 69.0 | 28.0 |
| ZnO/BA-OCH₃/Au | 0.65 | 9.48 | 0.52 | 3.22 | 287.1 | 2.1 |
| ZnO/BA-CH₃/Au | 0.59 | 8.82 | 0.43 | 2.22 | 209.3 | 8.6 |
| ZnO/BA-H/Au | 0.59 | 8.44 | 0.32 | 1.60 | 162.9 | 15.3 |
| ZnO/Au | 0.57 | 5.53 | 0.23 | 0.72 | 94.2 | 28.7 |
| ZnO/BA-SH/Au | 0.31 | 5.79 | 0.30 | 0.53 | 82.6 | 19.0 |
| ZnO/BA-CF₃/Au | 0.25 | 5.66 | 0.31 | 0.45 | 77.3 | 23.1 |
| ZnO/BA-CN/Au | 0.17 | 5.39 | 0.27 | 0.25 | 42.2 | 22.1 |

### Example 2

### Photovoltaic Devices Having Zinc Oxide Nanoparticles Modified with Aliphatic Chain SAMs

This example describes a solution-based processing method for fabricating PV devices that include an SAM-modified ZnO/metal bilayer cathode. Similar to Example 1, a series of conjugated carboxylic-acid SAMs with various dipoles were used to tune the contact property between the ZnO layer and three different metal electron-collecting electrodes: Al, Ag, and Au. Self-assembled molecules used in this example include lauric acid (LA), mercaptoundecanoic acid (MUA), and perfluorotetradecanoic acid (PFTDA). The devices show dramatically improved efficiencies, even when high work-function metals, such as Ag and Au, were used as electron-collecting electrodes.

Device fabrication: ITO-coated glass substrates (15 Ω/□) were cleaned in an ultrasonic bath with detergent, DI water, acetone, and isopropyl alcohol and then dried under a N₂ stream. The substrates were then treated with oxygen plasma for 10 min. A 50 nm hole-transport layer of PEDOT:PSS (Bayer AG) was then spin-coated on the substrate from an aqueous solution followed by annealing the film at 140° C. for 10 min in air. The substrates were then transferred into an argon-filled glove box. The chlorobenzene solution comprising a P3HT (25 mg mL⁻¹) and PCBM (15 mg mL⁻¹) were then spin-coated on the PEDOT:PSS layer to achieve a 200 nm thick BHJ photovoltaic layer. The P3HT:PCBM film was then annealed on a hot plate inside the glove box at 160° C. for 10 min. After the substrate was cooled to room temperature, a 40-50 nm thin film of ZnO nanoparticles were spin-coated on the photovoltaic layer from 1-butanol after filtering through a 0.2 μm PTFE filter. After the solvent dried, the ZnO NP film was insoluble in alcoholic solvents. The self-assembled molecules were then deposited on the ZnO surface using a two-step spin-coating process. First, 1 mM of the molecules in ethanol was spin-coated on the ZnO film, a monolayer of the molecules was formed through the chemical bonding between carboxylic-acid and ZnO. To remove physically adsorbed molecules, a second spin-coating using pure ethanol was applied. Finally, the substrates were transferred to a vacuum chamber installed inside the glove box. Subsequently the device was pumped down in vacuum (1×10⁻⁶ Torr) and 100 nm of metal film was deposited on top of the device at a slow deposition rate of 0.5 Å/s to minimize the potential damage of the self-assembled monolayer.

In this example, carboxylic-acid-based SAMs with saturated aliphatic and fluorinated aliphatic chains tune the contact properties between ZnO and metal (Al, Ag, and Au) electron-collecting electrodes to improve the performance of PV devices. Three different SAMs, including lauric acid (LA), mercaptoundecanoic acid (MUA) and perfluorotetradecanoic acid (PFTDA), were investigated because of their dipole and terminal groups. Both LA and MUA formed an interfacial dipole pointing away from the metal surface, which resulted in a decrease of the metal work-function. This allows an ohmic contact to be formed at the ZnO/metal junction.

The results of device testing are illustrated in FIGS. 6A (Al), 6B (Ag), and 6C (Au). Device testing results are summarized in Table 2.

The diode characteristics of devices modified with LA are strongly dependent on the choice of metal electron-collecting electrodes. Among the three different metals, Au was found to be the most efficient for LA-modified devices, having a PCE of 3.3%. Devices having Al and Ag as the electron-collecting electrodes showed comparatively worse (e.g., high Rₛ) diode characteristics.

SAMs with —SH terminated groups will form chemical bonds with the metal electrode through the metal-sulfur bond, leading to a decrease of contact resistance at the molecular junction by 1-2 order of magnitude when compare to that of —CH₃/metal junctions. The improvement of contact property using chemically bonded SAM/metal junction was demonstrated using MUA as an interfacial modifier. The diode characteristics of MUA modified devices were the best among all devices tested, having high V_{oc} of 0.65 eV and low Rₛ for all three different metal electron-collecting electrodes. In addition, the MUA-modified devices show significantly improved Rₛₕ, leading to a high FF over 0.61. The PCEs of MUA modified devices using Al, Ag, and Au, as electron-collecting electrodes are 4.6%, 4.4% and 4.3%, respectively, which show a 1.5-fold, 2.5-fold and 6-fold increase in performance compared to their corresponding unmodified (i.e., ZnO-only) devices.

Devices modified with PFTDA show small V_{oc} and poor diode characteristics due to the formation of an unfavorable interfacial dipole at the metal junction.

TABLE 2
Performance of photovoltaic devices, including those
with ZnO/benzoic acid-based SAM/metal electron-collecting
electrodes, averaged over ten devices.

| Electron- | | | | | | |
|---|---|---|---|---|---|---|
| collecting | | | | | Rₛₕ | Rₛ |
| electrode | Voc | J_{sc} | | PCE | (Ω · | (Ω · |
| Configuration | (V) | (mA/cm²) | FF | (%) | cm²) | cm²) |
| Al | 0.63 | 8.0 | 0.48 | 2.4 | 475.3 | 4.7 |
| ZnO/Al | 0.60 | 11.3 | 0.47 | 3.2 | 392.5 | 3.1 |
| ZnO/MUA/Al | 0.65 | 11.1 | 0.63 | 4.6 | 1163.1 | 1.8 |
| ZnO/LA/Al | 0.64 | 10.6 | 0.39 | 2.6 | 216.6 | 7.9 |
| ZnO/PFTDA/Al | 0.33 | 9.5 | 0.33 | 1.0 | 84.9 | 12.5 |
| Ag | — | — | — | — | — | — |
| ZnO/Ag | 0.54 | 8.8 | 0.37 | 1.7 | 174.4 | 9.6 |
| ZnO/MUA/Ag | 0.65 | 11.1 | 0.61 | 4.4 | 1046.7 | 2.1 |
| ZnO/LA/Ag | 0.62 | 8.4 | 0.24 | 1.2 | 98.1 | 14.3 |
| ZnO/PFTDA/Ag | 0.16 | 5.6 | 0.29 | 0.3 | 37.8 | 12.8 |
| Au | 0.17 | 7.8 | 0.31 | 0.4 | 38.5 | 10.9 |
| ZnO/Au | 0.57 | 5.5 | 0.23 | 0.7 | 94.2 | 28.7 |
| ZnO/MUA/Au | 0.65 | 10.7 | 0.61 | 4.3 | 779.2 | 2.7 |
| ZnO/LA/Au | 0.64 | 9.7 | 0.53 | 3.3 | 937.0 | 4.2 |
| ZnO/PFTDA/Au | 0.28 | 8.4 | 0.28 | 0.7 | 49.8 | 15.2 |

### Example 3

### Inverted Photovoltaic Devices Having Fullerene-Containing Self-Assembled Monolayers Modifying Metal Oxide Electron-Transport Layers

In this example, a spin-coating process is employed to modify the metal oxide (ZnO) interface of inverted PV devices with a fullerene-SAM. The SAM reduces the device series resistance by passivating the inorganic surface trap states as well as enhances the electronic coupling at ZnO/photovoltaic-layer interface. The SAM helps mediate forward charge transfer to reduce back recombination at the interface leading to improved fill factors and photocurrent densities. In addition, some inverted devices were fabricated in an ambient environment and performed comparably to those fabricated in an inert environment.

The PV devices used in this example are “inverted” because the transparent electrode, ITO, is used as the electron-collecting electrode (cathode), whereas traditional devices use ITO as the hole-collecting electrode (anode).

To fabricate the inverted solar cells, ITO-coated glass substrates (15 Ω/□) were cleaned with detergent, de-ionized water, acetone, and isopropyl alcohol. Substrates were then treated with oxygen plasma for 5 min. A thin layer of ZnO nanoparticles (50 nm), synthesized using the method described by Beek et al., was spin-coated onto ITO-coated glass.

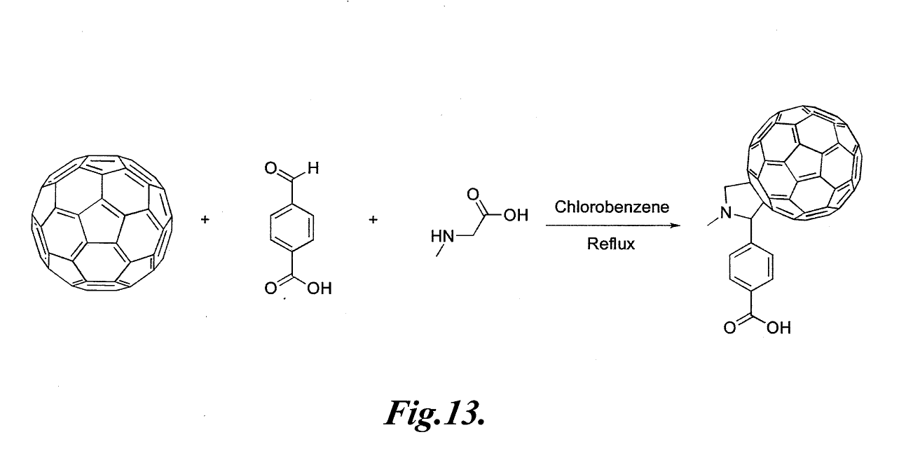

A fullerene-substituted benzoic acid (“BA-C₆₀”) was synthesized for use as an SAM. FIG. 13 is a scheme of the synthesis of BA-C₆₀. A mixture of 4-carboxybenzaldehyde (0.210 g, 1.40 mmol), C₆₀ (0.202 g, 0.28 mmol), and N-methylglycine (0.125 g, 1.40 mmol) in chlorobenzene (60 mL) was refluxed overnight under a nitrogen atmosphere. The solvent was removed by rotary evaporation under reduced pressure. The crude product was purified over silica gel column chromatography with toluene to toluene/THF (2/1) as the eluent to afford a brown-yellow solid of BA-C₆₀ (0.238 g, 95%). ¹H NMR (300 MHz, DMSO-d₆): δ 2.20 (s, 3H), 6.65 (s, 1H), 6.89 (s, 2H), 8.03 (d, J=8.4 Hz, 2H), 8.15 (d, J=8.4 Hz, 2H), 10.12 (s, 1H). C₇₀H₁₁NO₂: Calcd C 93.64, H 1.23, N 1.56; found C, 93.45; H, 1.31; N 1.62. ESI-MS (m/z): Calcd. 897.1; Found 897.0.

An SAM consisting of BA-C₆₀ was then formed on the ZnO surface using a two-step spin-coating process. First, a 1 mM solution of the molecules in tetrahydrofuran (THF)/chlorobenzene (CB) (1:1 v/v) was spin-coated on the ZnO film. To remove physically adsorbed molecules, a second spin-coating using pure THF was applied.

For BHJ devices, the photovoltaic layer was formed from a CB solution of P3HT (Rieke Metals) and PCBM (American Dye Source) (60 mg/ml) with a weight ratio of (1:0.6), which was transferred and spin-coated on the ZnO modified layer to achieve a thickness of (210 nm) in a glove box and annealed at 160° C. for 10 min. For heterojunction devices, P3HT (15 mg/ml) (50 nm) was spincoated onto the ZnO surface.

A hole-transporting layer was formed from a PEDOT:PSS solution (50 nm) spin-coated onto the photovoltaic layer and annealed for 10 min at 120° C. A silver electrode (100 nm) was then vacuum deposited on the hole-transport layer to complete the inverted device structure. The unencapsulated photovoltaic devices were tested under ambient conditions using a Keithley 2400 SMU and an Oriel Xenon lamp (450 W) with an AM1.5 filter. The light intensity was calibrated to 100 mW/cm² using a calibrated standard silicon solar cell with a KG5 filter which is traced to the National Renewable Energy Laboratory.

Some devices were ambiently (i.e., STP in air) processed. For ambient processing, all steps, including spin-coating and annealing were performed outside of the glovebox.

The device architecture is illustrated in FIG. 11D.

The ZnO surface was characterized by taking multiple advancing contact angle measurements from various locations on layers modified with and without the BA-C₆₀ SAM. The contact angle of the ZnO surface to de-ionized water prior to SAM modification was 23°. The formation of the BA-C₆₀ SAM on the ZnO surface was confirmed by the increase in contact angle to 64.

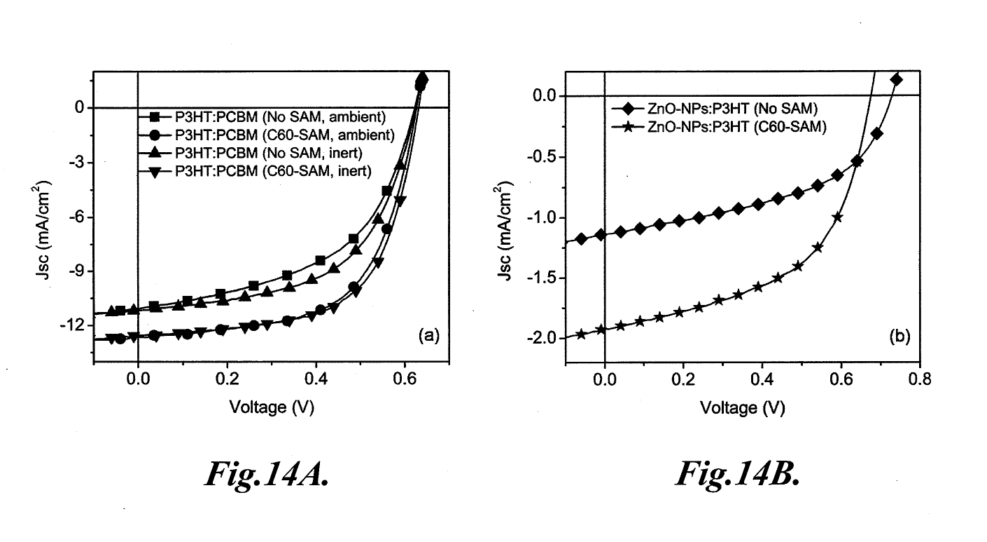

Table 3 summarizes the average performance of bulk-P3HT/PCBM heterojunction (BHJ) and P3HT/ZnO heterojunction (HJ) inverted devices with and without the BA-C₆₀ SAM. FIGS. 14A (BHJ) and 14B (HJ) illustrate the performance of inverted devices.

The unmodified BHJ device performance processed under inert conditions had an average power-conversion efficiency (PCE) of 3.7%. Comparing this to the one processed in ambient showed a decrease in PCE to 3.3%. The device characteristics of the two have similar open-circuit voltage (V_{oc}) and short-circuit current density (J_{sc}). The decrease in performance is a result of a lower fill factor (FF) of 50.8% in the ambient processed device compared to 55.4% in the inert processed device. The series resistances (Rₛ) of the devices were estimated from the inverse gradient of the J-V curve at 1V under illumination, showing a higher Rₛ of 3.1Ω·cm² for the ambient-processed device compared 2.6Ω·cm² for the inert-processed devices. The increase in resistance can be attributed to the absorption of O₂ on the ZnO surface under ambient condition, which is known to capture free electrons and create a low conductivity region near the surface.

The performance of inverted devices can be improved by modifying the ZnO surface with a BA-C₆₀ SAM. The PCE is improved by over 20% compared to unmodified devices, resulting in an average PCE of 4.5%. The highest PCE of 4.9% resulted from devices fabricated under inert conditions, with an improvement in both the FF from 55.4% to 60.6% and J_{sc} from 10.8 mA/cm² to 12.0 mA/cm². This improvement can be attributed to better electronic coupling of the inorganic/organic interface from the BA-C₆₀ SAM through the process of photo-induced charge transfer. This helps mediate forward charge transfer and reduces back charge recombination at the interface which leads to improved photocurrent and charge selectivity. Furthermore, devices modified using the BA-C₆₀ SAM also have improved Rₛ of 2Ω·cm². The J-V characteristics of the bulk heterojunction inverted solar cells processed in inert and ambient conditions are illustrated in FIG. 14A. There is no observable difference in J_{sc} in both cases but a slightly decrease in FF for the ambient processed devices. The insensitivity of the SAM modified devices to ambient process is due to the passivation of ZnO surface with the carboxylate-bonded BA-C₆₀ SAM which reduces O₂ absorption on the ZnO surface and improves the interfacial properties.

To investigate photo-induced charge transfer at the ZnO/SAM/photovoltaic interface, bilayer heterojunction (HJ) devices of ZnO modified with and without the BA-C₆₀ SAM and pristine P3HT were fabricated. The effect of the BA-C₆₀ SAM on the exciton dissociation efficiency can be studied because the only exciton dissociation site in this device structure is at the n-type ZnO/p-type P3HT interface. J-V data for HJ devices are illustrated in FIG. 14B and summarized in Table 3. Devices modified with the BA-C₆₀ SAM show almost a factor of two improvement in power-conversion efficiency compared to unmodified HJ devices. Both the FF and J_{sc} are improved from 46.7% to 54.2% and from 1.08 mA/cm² to 1.83 mA/cm², respectively. However, the V_{oc} of the modified devices decrease due to the fact that exciton dissociation happens at the BA-C₆₀/P3HT interface and not the ZnO/P3HT interface. It is known that the V_{oc} between fullerenes and P3HT is usually less than 0.7 V while between ZnO and P3HT can be greater than 0.7 V. The improvement is attributed to the C₆₀ moiety being an effective electron acceptor (n-type) under illumination due to photoinduced electron transfer from P3HT to BA-C₆₀.

TABLE 3
Performance of inverted photovoltaic devices, including
devices having fullerene-modified SAM enhancement
layers, averaged over ten devices.

| Processing | Photovoltaic | | Voc | Jsc | FF | PCE |
|---|---|---|---|---|---|---|
| Atmosphere | Material | SAM | (V) | (mA/cm²) | (%) | (%) |
| Inert | P3HT:PCBM | None | 0.63 | 10.8 | 55.4 | 3.74 |
| Inert | P3HT:PCBM | BA-C60 | 0.63 | 12.0 | 60.6 | 4.54 |
| Ambient | P3HT:PCBM | None | 0.62 | 10.5 | 50.8 | 3.32 |
| Ambient | P3HT:PCBM | BA-C60 | 0.63 | 12.0 | 59.5 | 4.45 |
| Inert | P3HT | None | 0.75 | 1.08 | 46.7 | 0.37 |
| Inert | P3HT | BA-C60 | 0.67 | 1.83 | 54.2 | 0.67 |

### Example 4

### Inverted Photovoltaic Devices Having Zinc Oxide Electron-Transport Layers Unmodified by SAMs

Inverted photovoltaic devices incorporating ZnO electron-transport layers were fabricated without a SAM monolayer. Devices were fabricated substantially as described in Example 3, although no SAM layer was deposited. The electron-transport layer was varied such that devices were fabricated with ZnO sol-gel or ZnO nanoparticles. Additionally, the substrate was either glass or plastic. A BHJ of P3HT:PCBM was the photovoltaic layer and PEDOT:PSS was the hole-transporting layer.

LiF is a traditional electron-transport material and a non-inverted device was fabricated with LiF for comparison to the inverted ZnO devices.

ZnO NP devices were fabricated as described in Example 3. ZnO sol-gel devices included a ZnO layer deposited as follows. Onto the ITO layer, a zinc acetate solution (160 g/L) in 96% 2-methoxy ethanol and 4% ethanolamine to produce a sol-gel. The sol-gel was then annealed in air for 5 min. at 400° C.

All devices were tested as described above. Test results are summarized in Table 4.

TABLE 4
Performance of photovoltaic devices, including
inverted devices having zinc oxide electron-transport
layers, averaged over ten devices.

| Device | | Voc | Jsc | FF | PCE |
|---|---|---|---|---|---|
| Structure | ZnO Form | (V) | (mA/cm²) | (%) | (%) |
| Glass/ITO/LiF/ | N/A | 0.598 | 7.87 | 50.9 | 2.4 |
| PV/HTL/Al | | | | | |
| Glass/ITO/ZnO/ | Sol-gel | 0.617 | 11.08 | 51.3 | 3.51 |
| PV/HTL/Ag | | | | | |
| Glass/ITO/ZnO/ | NP | 0.623 | 10.69 | 54.2 | 3.60 |
| PV/HTL/Ag | | | | | |
| Plastic/ITO/Zn | NP | 0.624 | 9.81 | 53.9 | 3.30 |
| O/PV/HTL/Ag | | | | | |

The ZnO not only improves the performance of devices, but also allows for inverted devices to be fabricated that outperform traditional devices. Nanoparticle ZnO was found to provide improved properties compared to not only traditional devices, but also inverted devices that incorporate annealed sol-gel ZnO as the electron-transport layer. Thus, ZnO NPs were found to be a high-performing electron-transport material that is processable at low temperatures, particularly when compared to the annealed sol-gel of ZnO, which produced efficient devices but requires high temperatures to form.

The fabrication of inverted devices provides a route to long-term device stability in an ambient environment. The inverted devices described above with reference to Table 4 were periodically tested for 40 days and the inverted devices all retained greater than 80% of their efficiency, while the traditional devices became inoperable within five days.

### Example 5

### Inverted Photovoltaic Devices Having Titanium Oxide Electron-Transport Layers Modified by SAMs

Titanium oxide (TiOx) was integrated into inverted devices as an electron-transport layer. A series of devices were fabricated and tested, including devices having SAMs intermediate the TiOx and the P3HT/PCBM BHJ photovoltaic layer.

Devices were fabricated and tested as described in Example 3. SAMs used include BA-C₆₀, terthiophene (TT), benzoic acid (BA), and lauric acid (LA). TiOx films were formed on ITO/glass substrates by spin coating titanium isopropoxide diluted in n-butyl alcohol. The SAMs were formed by immersing the TiOx surface in 0.1 mM solutions of the monolayer compounds in THF-ethanol (1:1). The result of device testing are summarized in Table 5.

TABLE 5
Performance of inverted photovoltaic devices, including
those with SAM-modified TiOx as the electron-collecting
electrodes, averaged over ten devices.

| | Voc | J_{sc} | | PCE | Rₛ | Rₛₕ |
|---|---|---|---|---|---|---|
| SAM | (V) | (mA/cm²) | FF | (%) | (Ω · cm²) | (Ω · cm²) |
| None | 0.61 | 9.80 | 46.9 | 2.8 | 13 | 380 |
| BA-C₆₀ | 0.62 | 10.6 | 57.2 | 3.8 | 2.4 | 1010 |
| TT | 0.60 | 10.0 | 56.2 | 3.4 | 3.5 | 880 |
| BA | 0.60 | 10.5 | 50.2 | 3.2 | 2.7 | 580 |
| LA | 0.61 | 9.92 | 49.5 | 3.0 | 2.6 | 440 |

The devices modified with SAMs show improvement in all tested categories due to an improvement in charge selectivity and a reduction of charge-recombination losses between the photovoltaic layer and the electron-collecting electrode via the electron-transport layer. Additionally, the SAMs passivate surface traps to improve contact resistance.

While illustrative embodiments have been illustrated and described, it will be appreciated that various changes can be made therein without departing from the spirit and scope of the invention.

The embodiments of the invention in which an exclusive property or privilege is claimed are defined as follows:

1. A photovoltaic device, comprising:
(a) a hole-collecting electrode;
(b) a photovoltaic layer;
(c) an electron-collecting electrode; and
(d) an electron-transport layer comprising a metal oxide and a monolayer intermediate the electron-collecting electrode and the photovoltaic layer.

2. The device of claim 1, wherein the hole-collecting electrode comprises a material selected from the group consisting of a continuous metal, a metal grid, indium-tin oxide, and a conductive polymeric material.

3. The device of claim 1, wherein the photovoltaic layer comprises a bulk heterojunction layer.

4. The device of claim 1, wherein the electron-collecting electrode comprises a conductive metal grid.

5. The device of claim 1, wherein the metal oxide is selected from the group consisting of zinc oxide and titanium oxide.

6. The device of claim 1, wherein the metal oxide comprises a metal oxide in a form selected from the group consisting of nanoparticles and an annealed sol-gel.

7. The device of claim 1, wherein the monolayer is a self-assembled monolayer.

8. The device of claim 7, wherein the self-assembled monolayer has electron-transporting properties.

9. The device of claim 7, wherein the self-assembled monolayer comprises a functionalized π-conjugated compound.

10. The device of claim 7, wherein the self-assembled monolayer modifies the work function of the electron-collecting electrode.

11. The device of claim 7, wherein the self-assembled monolayer comprises a functionalized π-conjugated compound selected from the group consisting of a carboxylic-acid functionalized π-conjugated compound, a phosphonic acid functionalized π-conjugated compound, and a catechol functionalized π-conjugated compound.

12. The device of claim 11, wherein the π-conjugated compound is selected from the group consisting of a C₆₀ compound, a C₇₀ compound, and a terthiophene compound.

13. The device of claim 1 further comprising a hole-transport layer.

14. The device of claim 1 further comprising a substrate.

15. The device of claim 14, wherein the substrate abuts an electrode selected from the group consisting of the electron-collecting electrode and the hole-collecting electrode.

16. The device of claim 1, wherein the photovoltaic layer is intermediate the hole-collecting electrode and the electron-collecting electrode; the electron-transport layer is intermediate the photovoltaic layer and the electron-collecting electrode; and the monolayer is intermediate the metal oxide and the electron-collecting electrode.

17. The device of claim 1, wherein the photovoltaic layer is intermediate the hole-collecting electrode and the electron-collecting electrode; the electron-transport layer is intermediate the photovoltaic layer and the electron-collecting electrode; and the monolayer is intermediate the metal oxide and the photovoltaic layer.

18. A method for making a photovoltaic device, comprising:
(a) forming a photovoltaic layer on a hole-collecting electrode;
(b) forming a metal oxide layer on the photovoltaic layer;
(c) forming a monolayer on the metal oxide layer; and
(d) forming an electron-collecting electrode on the monolayer.

19. The method of claim 18, wherein forming the metal oxide layer comprises a technique selected from the group consisting of spin coating, drop coating, blade coating, spray coating, screen-printing, inkjet printing, vapor deposition, and sol-gel annealing, and combinations thereof.

20. The method of claim 18, wherein forming the monolayer comprises a technique selected from the group consisting of spin coating, drop coating, immersion coating, spray coating, blade coating, and vapor deposition, and combinations thereof.

21. The method of claim 18 further comprising forming a hole-transport layer on the hole-collecting electrode.

22. The method of claim 18, wherein all steps of the method are performed in an oxygen-containing environment.

23. A method for making an inverted photovoltaic device comprising:
(a) forming a metal oxide layer on an electron-collecting electrode;
(b) forming a monolayer on the metal oxide layer;
(c) forming a photovoltaic layer on the monolayer; and
(d) forming a hole-collecting electrode on the photovoltaic layer.

24. The method of claim 23, wherein forming the metal oxide layer comprises a technique selected from the group consisting of spin coating, drop coating, blade coating, spray coating, screen-printing, inkjet printing, vapor deposition, and sol-gel annealing, and combinations thereof.

25. The method of claim 23, wherein forming the monolayer comprises a technique selected from the group consisting of spin coating, drop coating, immersion coating, spray coating, blade coating, and vapor deposition, and combinations thereof.

26. The method of claim 23 further comprising forming a hole-transport layer on the photovoltaic layer.

27. The method of claim 23, wherein all steps of the method are performed in an oxygen-containing environment.

28. A method for generating an electrical current, comprising exposing the photovoltaic layer of the photovoltaic device of claim 1 to electromagnetic radiation of a wavelength sufficient to generate electrons and holes in the photovoltaic layer.

29. An optoelectronic device, comprising:
(a) an anode;
(b) an active layer;
(c) a cathode;
(d) an electron-transport layer comprising a metal oxide and a monolayer intermediate the active layer and at least one of the anode and the cathode.

30. The optoelectronic device of claim 29, wherein the active layer is selected from the group consisting of a photovoltaic material and a light-emitting material.
